(19) United States
(12) Patent Application Publication
(10) Pub. No.: US 2025/0132301 A1
(43) Pub. Date: Apr. 24, 2025

(54) METAL LINES LOCATED BETWEEN ETCH STOP LAYERS AND SEPARATED BY AIR GAPS AND METHODS OF FORMING THE SAME

(71) Applicant: WESTERN DIGITAL TECHNOLOGIES, INC.,, SAN JOSE, CA (US)

(72) Inventor: Fumitaka AMANO, Yokkaichi (JP)

(21) Appl. No.: 18/491,297

(22) Filed: Oct. 20, 2023

(51) Int. Cl. H01L 25/18; H01L 21/768; H01L 23/522; H01L 23/528; H01L 23/532; H10B 41/27; H10B 41/30; H10B 41/40; H10B 43/10; H10B 43/27; H10B 43/30; H10B 43/40

(52) U.S. Cl. CPC H01L 25/18; H01L 21/76807; H01L 21/7682; H01L 21/76831; H01L 21/76877; H01L 23/5226; H01L 23/5283; H01L 23/53295; H10B 41/27; H10B 41/30; H10B 41/40; H10B 43/10; H10B 43/27; H10B 43/30; H10B 43/40

(57) ABSTRACT

A semiconductor structure includes contact-level metal structures embedded in a contact-level dielectric layer, a via-level dielectric layer overlying the contact-level dielectric layer, an etch-stop dielectric layer overlying the via-level dielectric layer, integrated line-and-via structures each including a metal line portion and at least one via portion, discrete etch-stop dielectric cap rails that overlie top surfaces of the respective metal line portions, dielectric rails located between neighboring pairs of the metal line portions, and air gaps located between neighboring pairs of the metal line portions and at least partially enclosed by the respective dielectric rails.

### FIELD

The present disclosure relates generally to the field of semiconductor devices, and particularly to semiconductor devices including metal lines located between etch stop layers and separated by air gaps, and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure comprises: a contact-level dielectric layer overlying semiconductor devices; contact-level metal structures embedded in the contact-level dielectric layer and electrically connected to a respective electrical node of the semiconductor devices; a via-level dielectric layer overlying the contact-level dielectric layer; an etch-stop dielectric layer overlying the via-level dielectric layer; integrated line-and-via structures each comprising a metal line portion and at least one via portion, wherein each via portion of the integrated line-and-via structures vertically extends through the etch-stop dielectric layer and the via-level dielectric layer and contacts a top surface of a respective one of the contact-level metal structures, and the metal line portions are laterally spaced apart from each other along a first horizontal direction and laterally extend along a second horizontal direction; discrete etch-stop dielectric cap rails that overlie top surfaces of the respective metal line portions; dielectric rails located between neighboring pairs of metal line portions of the metal line portions; and air gaps located between neighboring pairs of the metal line portions and at least partially enclosed by the respective dielectric rails.

According to another aspect of the present disclosure, a method of forming a device structure is provided. The method comprises: forming contact-level metal structures embedded in a contact-level dielectric layer; forming a via-level dielectric layer over the contact-level dielectric layer; forming an etch-stop dielectric layer over the via-level dielectric layer; forming via cavities through the etch-stop dielectric layer and the via-level dielectric layer; forming at least one metallic material layer in the via cavities and over the etch-stop dielectric layer; forming an etch-stop dielectric cap material layer over the at least one metallic material layer; patterning the etch-stop dielectric cap material layer and the at least one metallic material layer, wherein patterned portions of the at least one metallic material layer comprise integrated line-and-via structures each comprising a metal line portion and at least one via portion, wherein each via portion of the integrated line-and-via structures vertically extends through the etch-stop dielectric layer and the via-level dielectric layer and contacts a top surface of a respective one of the contact-level metal structures, and the metal line portions are laterally spaced apart from each other along a first horizontal direction and laterally extend along a second horizontal direction, and wherein patterned portions of the etch-stop dielectric cap material layer comprise etch-stop dielectric cap rails that overlie top surfaces of the metal line portions; and forming dielectric rails between neighboring pairs of metal line portions of the metal line portions.

According to yet another aspect of the present disclosure, a method of forming a device structure is provided. The method comprises: forming contact-level metal structures embedded in a contact-level dielectric layer; forming a via-level dielectric layer over the contact-level dielectric layer; forming an etch-stop dielectric layer over the via-level dielectric layer; forming a sacrificial template material layer over the etch-stop dielectric layer; forming integrated line-and-via cavities, wherein each of the integrated line-and-via cavities comprises a respective line cavity that is formed through the sacrificial template material layer and at least one via cavity that is formed through the etch-stop dielectric layer and the via-level dielectric layer; forming integrated line-and-via structures in the integrated line-and-via cavities, wherein each of the integrated line-and-via structures comprises a metal line portion and at least one via portion; forming recess cavities by vertically recessing the metal line portions of the integrated line-and-via structures; forming etch-stop dielectric cap rails in the recess cavities; removing remaining portions of the sacrificial template material layer; and forming dielectric rails between neighboring pairs of metal line portions of the metal line portions.

### BRIEF DESCRIPTION OF THE DRAWINGS

FIG. 1 is a schematic vertical cross-sectional view of an exemplary structure for forming a memory die after formation of a stopper insulating layer, in-process source-level material layers, and an alternating stack of insulating layers and sacrificial material layers over a carrier substrate according to an embodiment of the present disclosure.

FIG. 2 is a schematic vertical cross-sectional view of the exemplary structure after formation of stepped surfaces and a retro-stepped dielectric material portion according to an embodiment of the present disclosure.

FIG. 3A is a schematic vertical cross-sectional view of the exemplary structure after forming memory openings and support openings according to an embodiment of the present disclosure.

FIG. 3B is a top-down view of the exemplary structure of FIG. 3A. The vertical plane A-A′ is the cut plane of the vertical cross-sectional view of FIG. 3A.

FIG. 4 is a schematic vertical cross-sectional view of the exemplary structure after formation of support pillar structures according to an embodiment of the present disclosure.

FIGS. 5A-5D are sequential vertical cross-sectional views of a memory opening during formation of a memory opening fill structure according to an embodiments of the present disclosure.

FIG. 6A is a vertical cross-sectional view of the exemplary structure after formation of memory opening fill structures according to an embodiment of the present disclosure.

FIG. 6B is a top-down view of the exemplary structure of FIG. 6A. The vertical plane A-A′ is the cut plane of the vertical cross-sectional view of FIG. 6A.

FIG. 7A is a vertical cross-sectional view of the exemplary structure after formation of isolation trenches according to an embodiment of the present disclosure.

FIG. 7B is a top-down view of the exemplary structure of FIG. 7A. The vertical plane A-A′ is the cut plane of the vertical cross-sectional view of FIG. 7A.

FIG. 8 is a vertical cross-sectional view of the exemplary structure after formation of a source-level cavity according to an embodiment of the present disclosure.

FIG. 9 is a vertical cross-sectional view of the exemplary structure after formation of a source contact layer according to an embodiment of the present disclosure.

FIG. 10 is a vertical cross-sectional view of the exemplary structure after formation of laterally-extending cavities according to an embodiment of the present disclosure.

FIGS. 11A-11D are sequential vertical cross-sectional views of a region of the exemplary structure during formation of an outer blocking dielectric layer and an electrically conductive layer in each of the laterally-extending cavities according to an embodiment of the present disclosure.

FIG. 12 is a vertical cross-sectional view of the exemplary structure after formation of electrically conductive layers according to an embodiment of the present disclosure.

FIG. 13A is a vertical cross-sectional view of the exemplary structure after formation of lateral isolation trench fill structures and contact via structures according to an embodiment of the present disclosure.

FIG. 13B is a top-down view of the exemplary structure of FIG. 13A. The vertical plane A-A′ is the cut plane of the vertical cross-sectional view of FIG. 13A.

FIGS. 14A-14G are sequential vertical cross-sectional views of a region of a first configuration of the exemplary structure during formation of a via-level dielectric layer, a composite line-level dielectric layer, and integrated line-and-via structures according to a first embodiment of the present disclosure.

FIGS. 15A-15I are sequential vertical cross-sectional views of a region of a second configuration of the exemplary structure during formation of a via-level dielectric layer, a composite line-level dielectric layer, and integrated line-and-via structures according to a second embodiment of the present disclosure.

FIG. 16A is a vertical cross-sectional view of the exemplary structure after the processing steps of FIG. 14F or FIG. 14G or FIG. 15I according to an embodiment of the FIG. 16B is a top-down view of the exemplary structure of FIG. 16A. The vertical plane A-A′ is the cut plane of the vertical cross-sectional view of FIG. 16A.

FIG. 17A is a vertical cross-sectional view of the exemplary structure after formation of a memory die according to an embodiment of the present disclosure.

FIG. 17B is a magnified view of a region of the first configuration of the exemplary structure of FIG. 17A.

FIG. 17C is a magnified view of a region of the second configuration of the exemplary structure of FIG. 17A.

FIG. 18 is a vertical cross-sectional view of a logic die according to an embodiment of the present disclosure.

FIG. 19 is a vertical cross-sectional view of the exemplary structure after formation of a bonded assembly of the memory die and the logic die according to an embodiment of the present disclosure.

FIG. 20 is a vertical cross-sectional view of the exemplary structure after removal of a carrier substrate from the memory die according to an embodiment of the present disclosure.

FIG. 21 is a vertical cross-sectional view of an alternative configuration of the exemplary structure after formation of an alternating stack of insulating layers and sacrificial material layers according to an alternative embodiment of the present disclosure.

FIG. 22 is a vertical cross-sectional view of the alternative configuration of the exemplary structure after formation of a memory die according to the alternative embodiment of the present disclosure.

### DETAILED DESCRIPTION

High density metal lines, such as bit lines, are subject to RC delay due to high capacitive coupling between the adjacent metal lines. The embodiments of the present disclosure are directed to semiconductor devices including bit lines located between etch stop layers and separated by air gaps and methods for manufacturing the same, the various aspects of which are described below. The air gaps reduce the capacitive coupling between adjacent bit lines, and thus also reduce the RC delay. Embodiments of the disclosure can be employed to form various structures including a multilevel memory structure, non-limiting examples of which include semiconductor devices such as three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

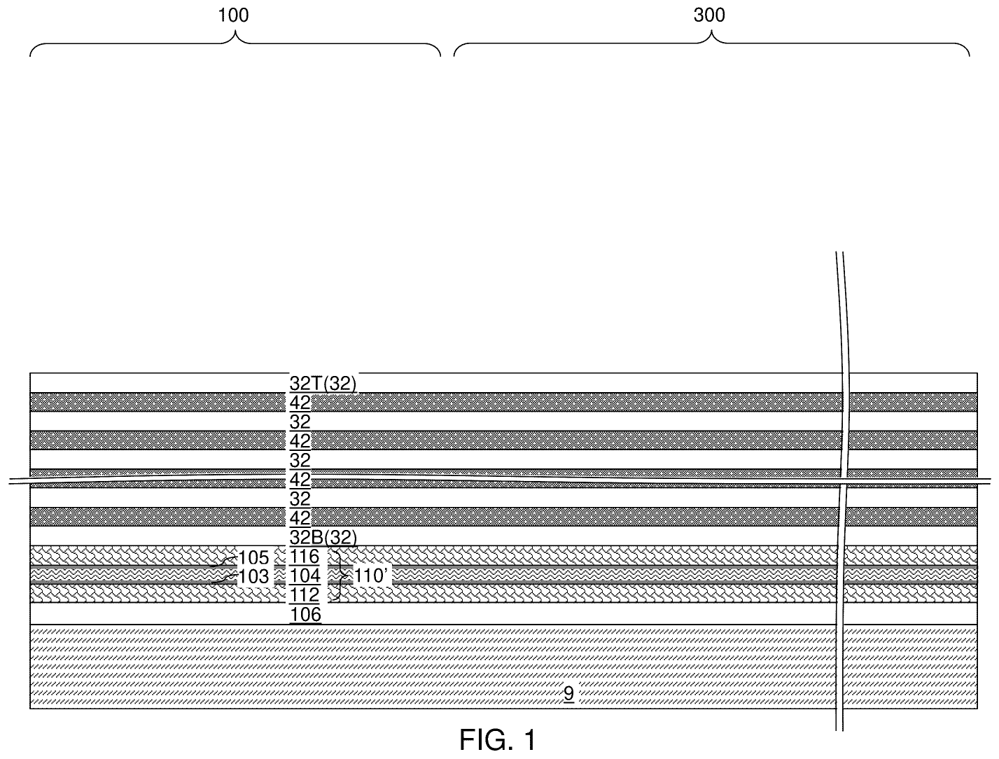

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper insulating layer 106 may be subsequently employed as a polishing stopper material layer. If an etch process such as a wet etch process is employed to subsequently remove the carrier substrate 9, the stopper insulating layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 50 nm to 600 nm, such as from 100 nm to 300 nm, although lesser and greater thicknesses may also be employed.

In-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

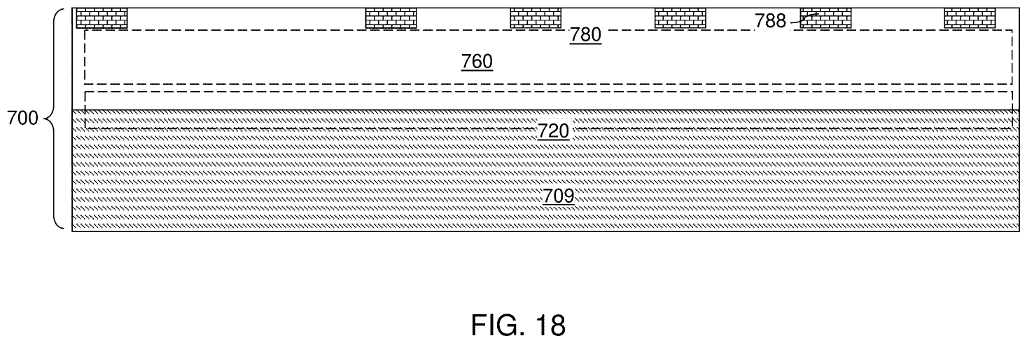

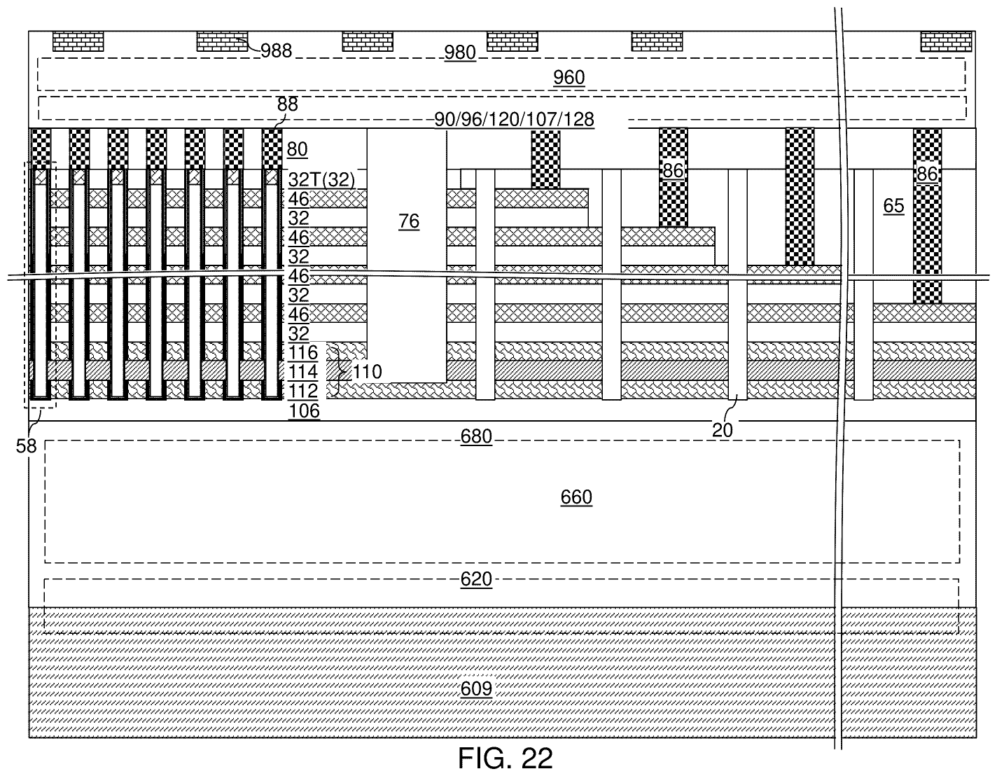

An alternating stack of first material layers and second material layers can be formed over the in-process source-level material layers 110′. In an alternative embodiment, the in-process source-level material layers 110′ and the stopper insulating layer 106 may be omitted, and the alternating stack is formed directly on a surface of the carrier substrate 9. In another alternative embodiment shown in FIG. 22, a peripheral circuit may be formed on the same substrate as the alternating stack. For example, the peripheral circuit may comprise word line driver regions, bit line driver regions, sense amplifier regions, input/output buffer regions, etc. In this alternative embodiment, a separate logic die described below with respect to FIG. 18 may not be necessary. In this alternative embodiment, the alternating stack may be deposited on the in-process source-level material layers 110′ or the in-process source-level material layers 110′ may be omitted, and the alternating stack may be deposited on the stopper insulating layer 106.

In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

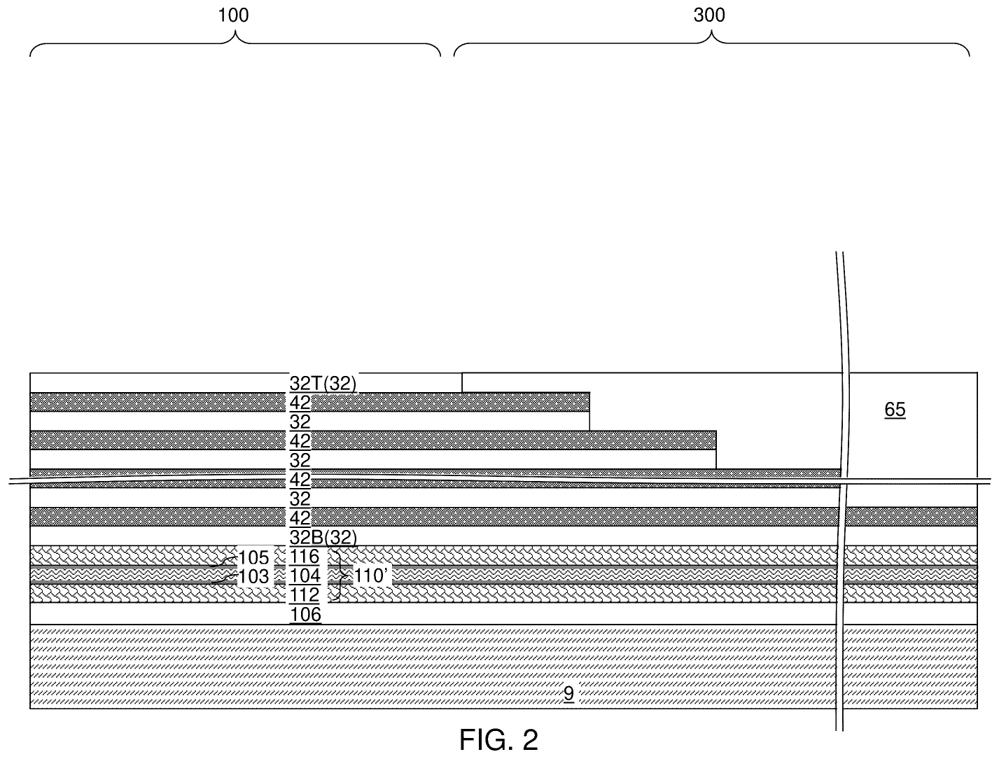

Referring to FIG. 2, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

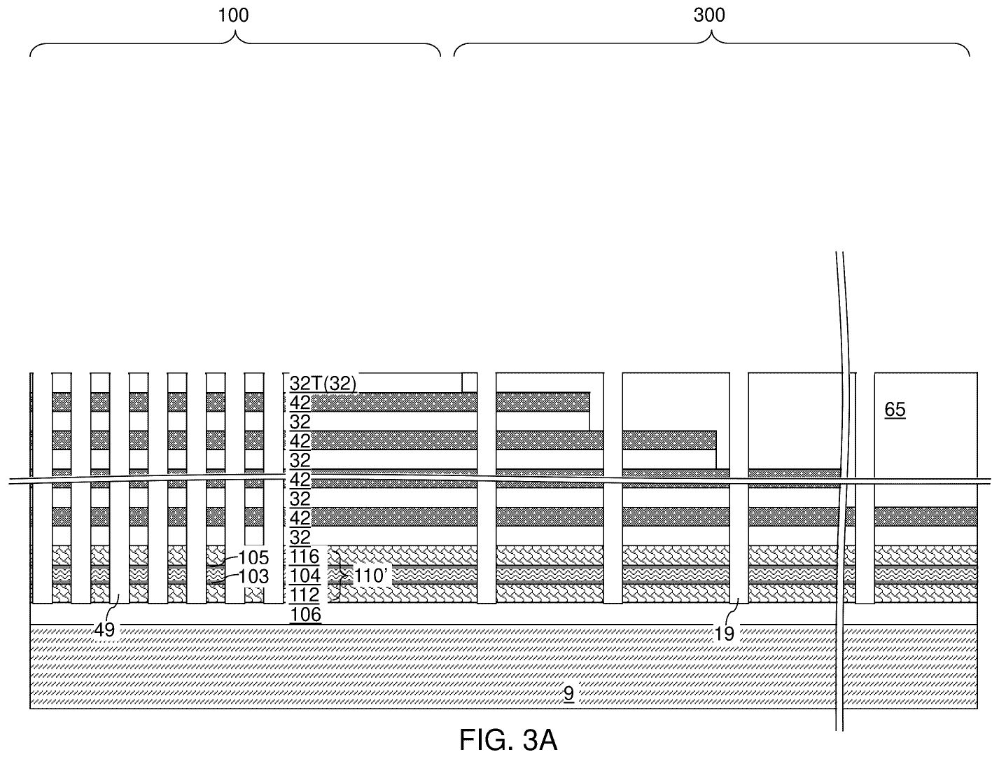

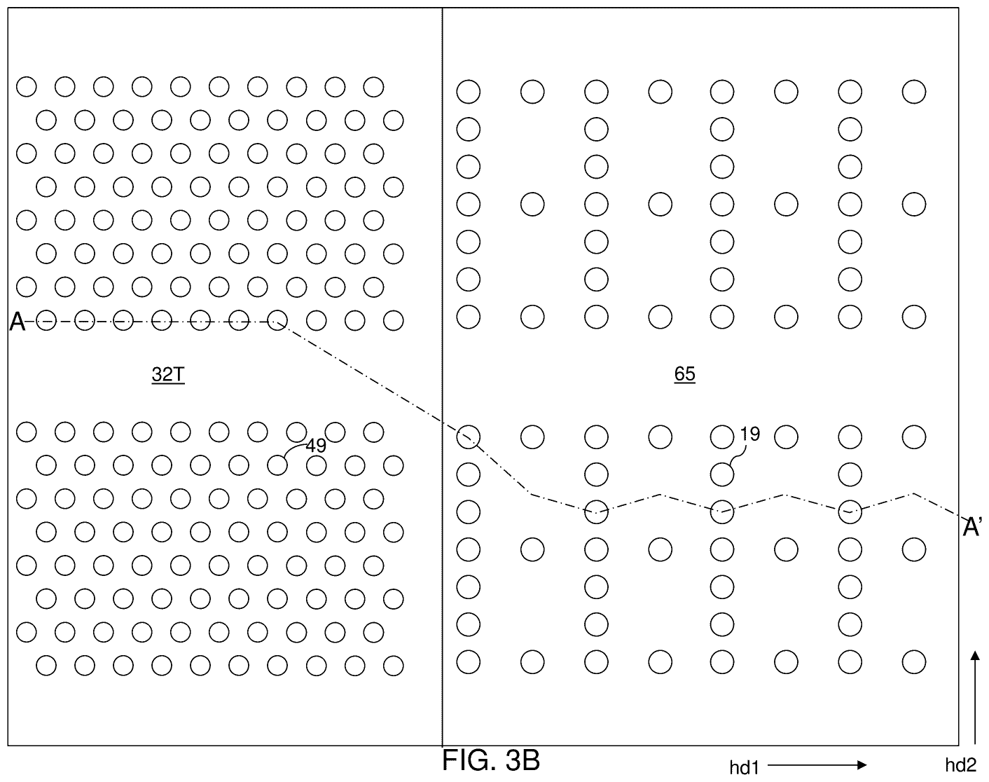

Referring to FIGS. 3A-3C, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and into the in-process source-level material layers 110′ In one embodiment, bottom surfaces of the memory openings 49 and the support openings 19 may be formed within the lower source-level semiconductor layer 112 or at an interface between the lower source-level semiconductor layer and the stopper insulating layer 106.

The support openings 19 may have a diameter in a range from 60 nm too 400 nm, such as from 120 nm to 300 nm, although lesser and greater thicknesses may be employed. The memory openings 49 may have a diameter in a range from 60 nm too 400 nm, such as from 120 nm to 300 nm, although lesser and greater thicknesses may be employed.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

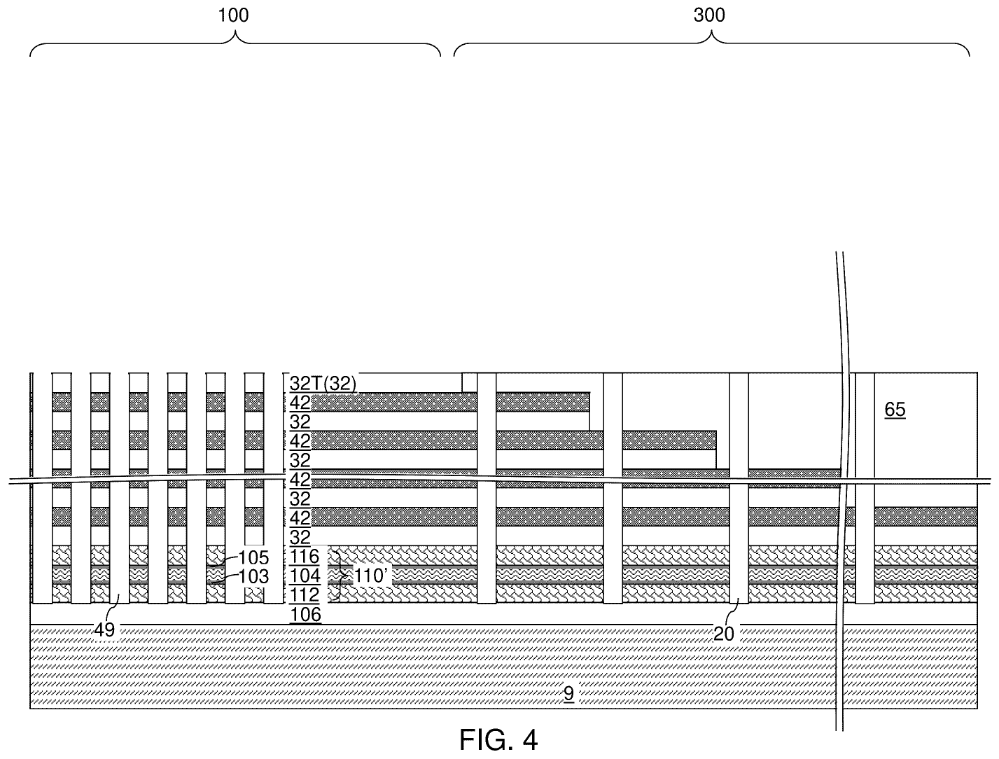

Referring to FIG. 4, an optional etch stop liner (not shown) and a sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

A dielectric fill material such as silicon oxide can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

Subsequently, the sacrificial memory opening fill structures and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

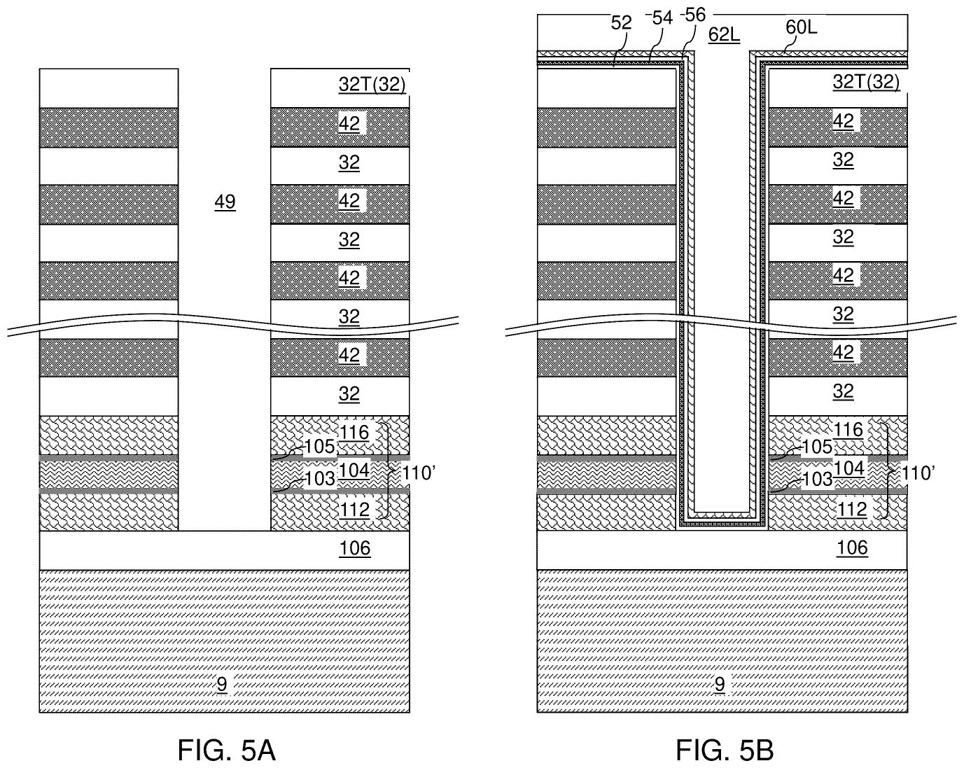

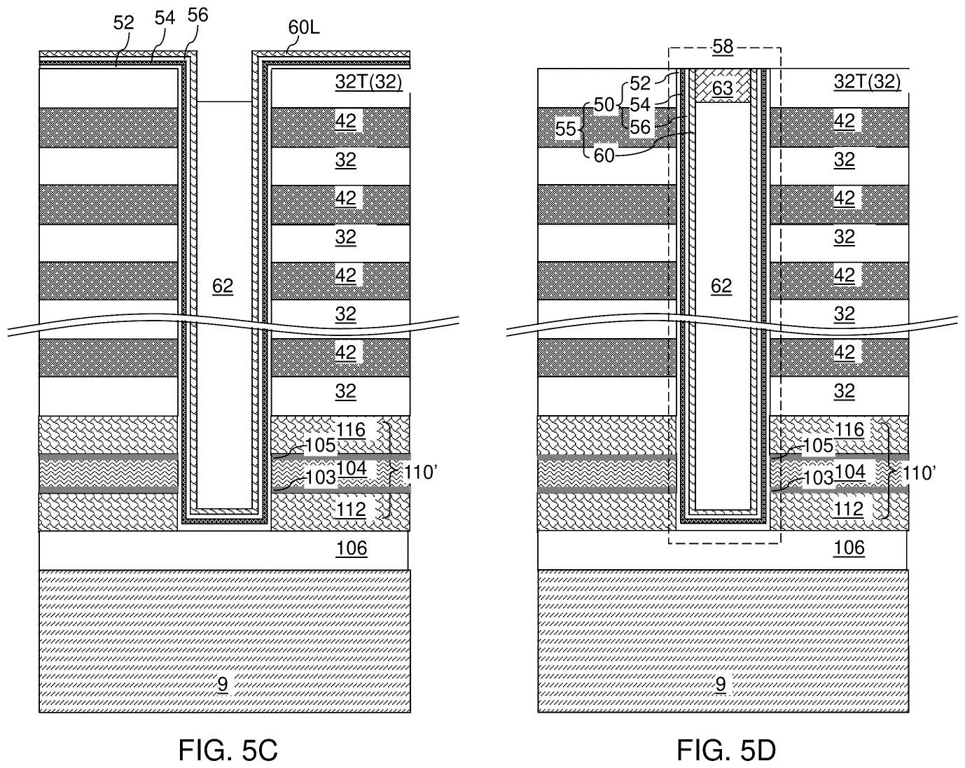

FIGS. 5A-5D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 5A, a memory opening 49 is illustrated after the processing steps of FIG. 4.

Referring to FIG. 5B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 5C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 5D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

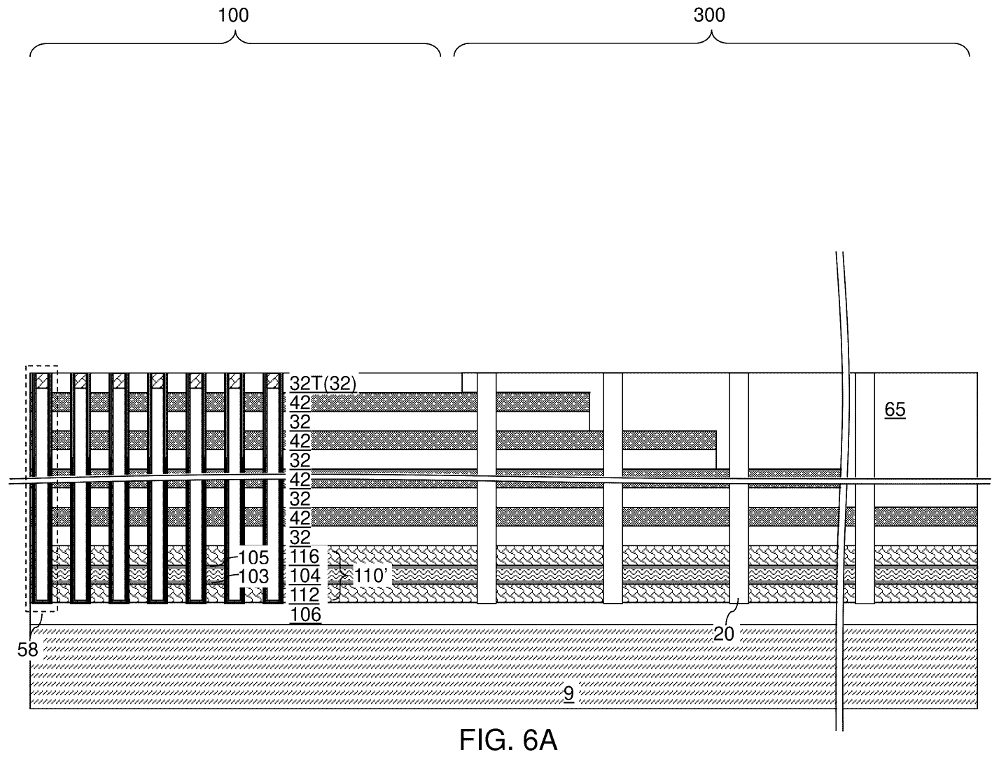

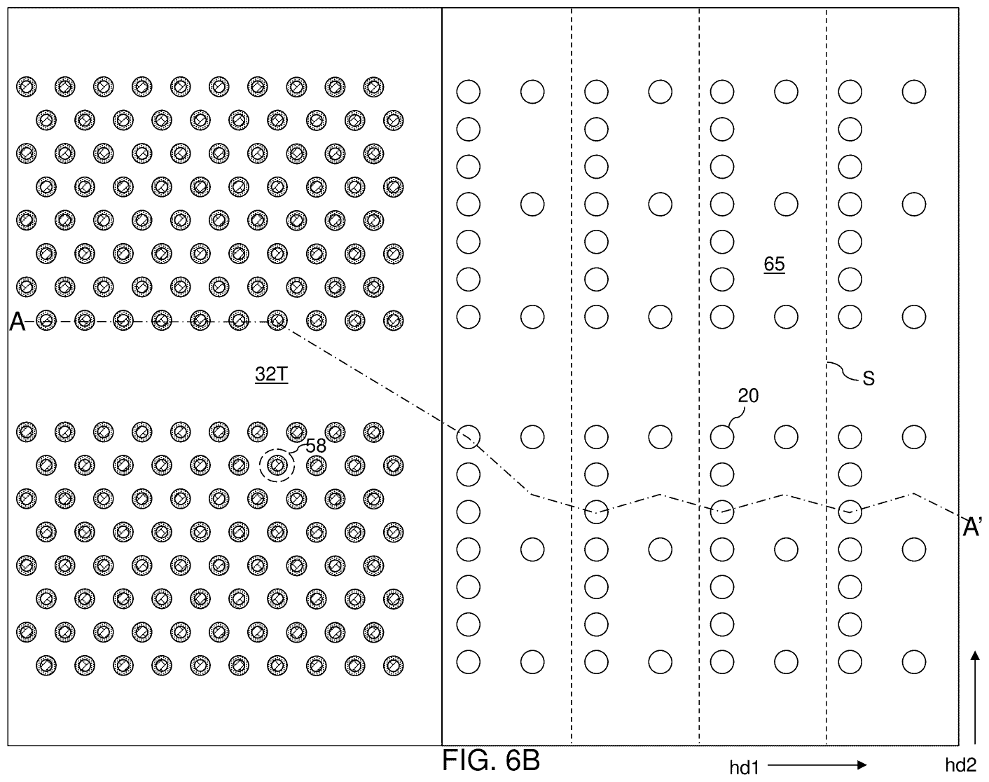

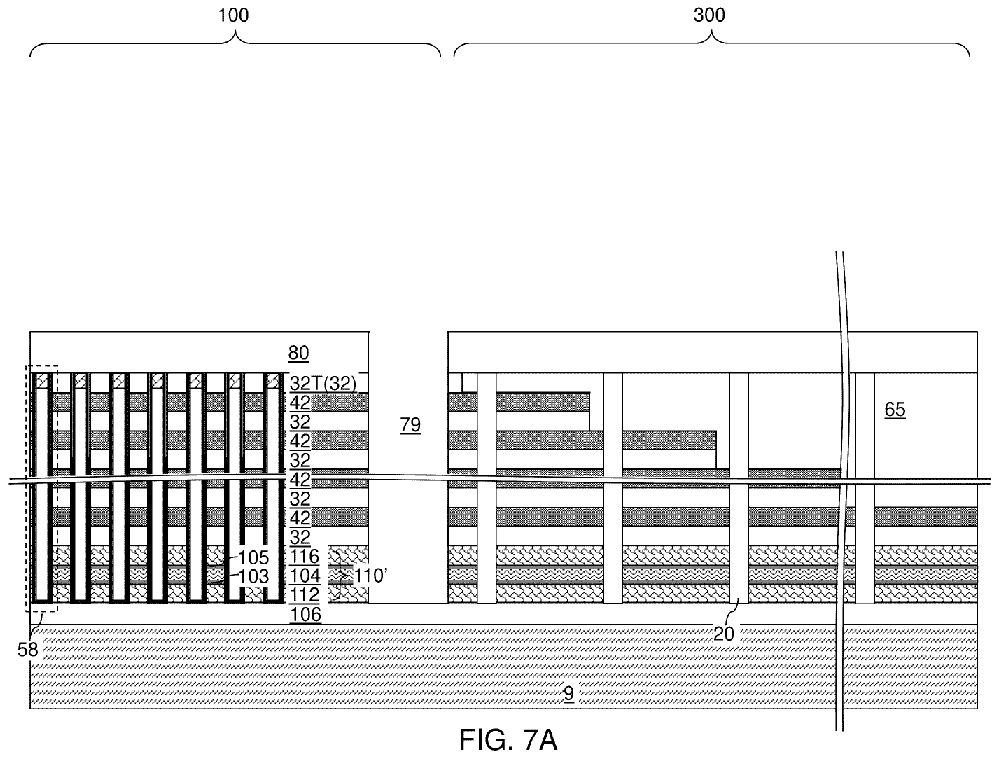

Referring to FIGS. 6A and 6B, the exemplary structure is illustrated after formation of memory opening fill structures 58 within the memory openings 49. Each of the memory opening fill structures 58 may comprise a memory film 50 and a vertical semiconductor channel 60. In summary, a combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

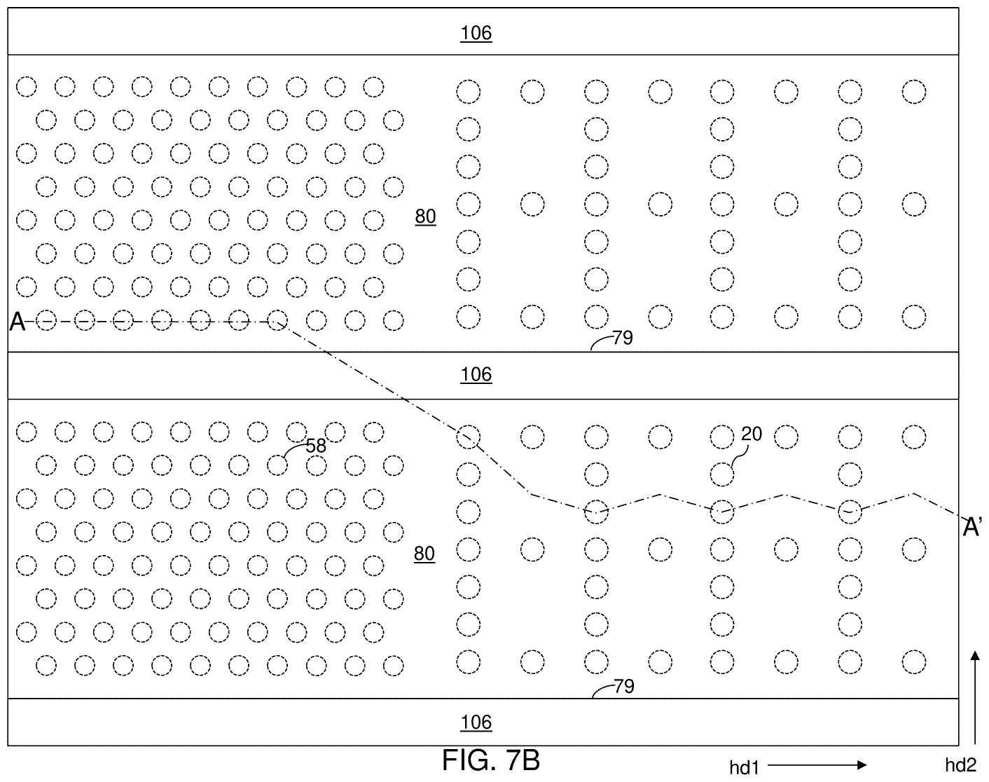

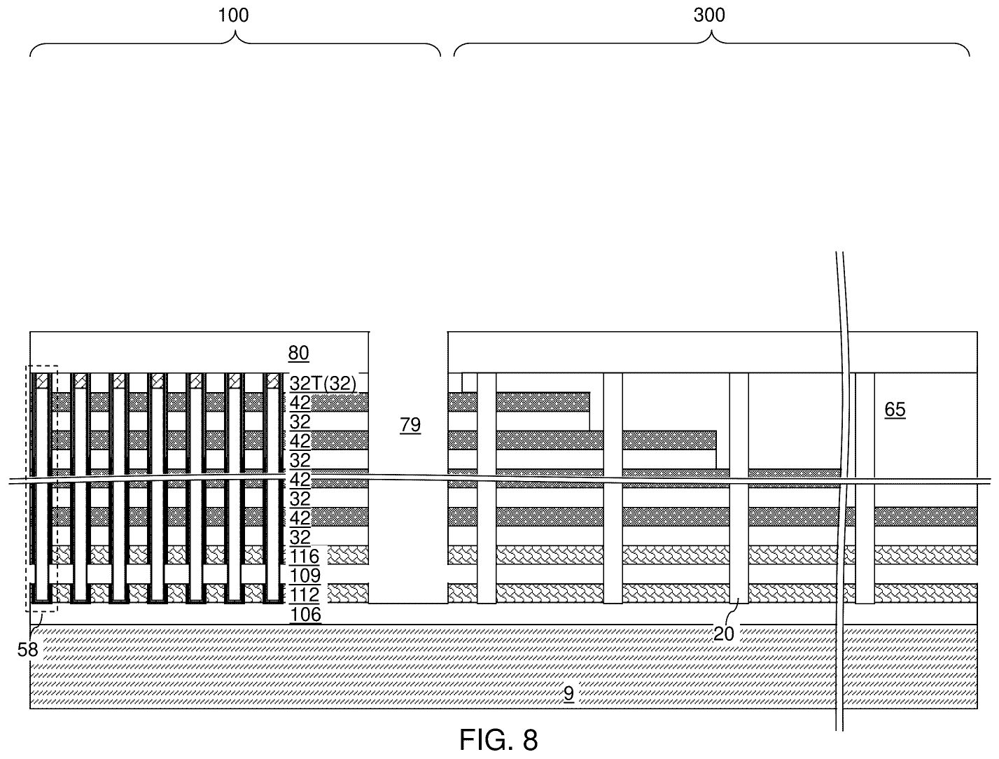

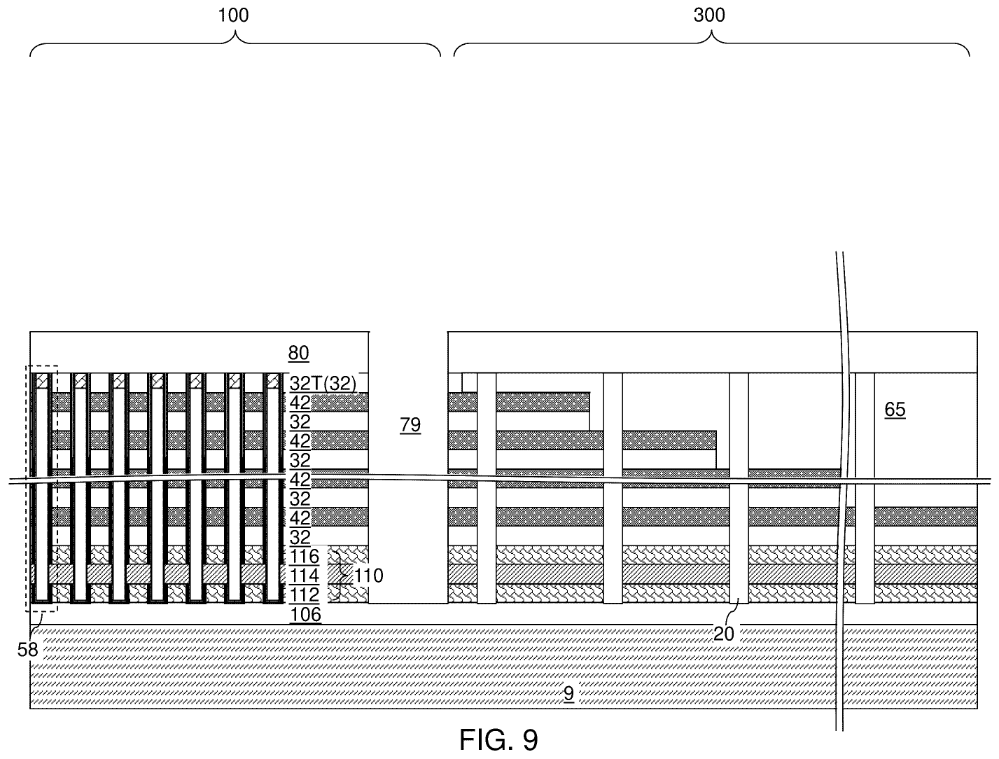

Referring to FIGS. 7A and 7B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the retro-stepped dielectric material portion 65, and the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The lateral isolation trenches 79 isolate adjacent memory blocks from each other along the second horizontal direction hd2. The photoresist layer can be subsequently removed, for example, by ashing.

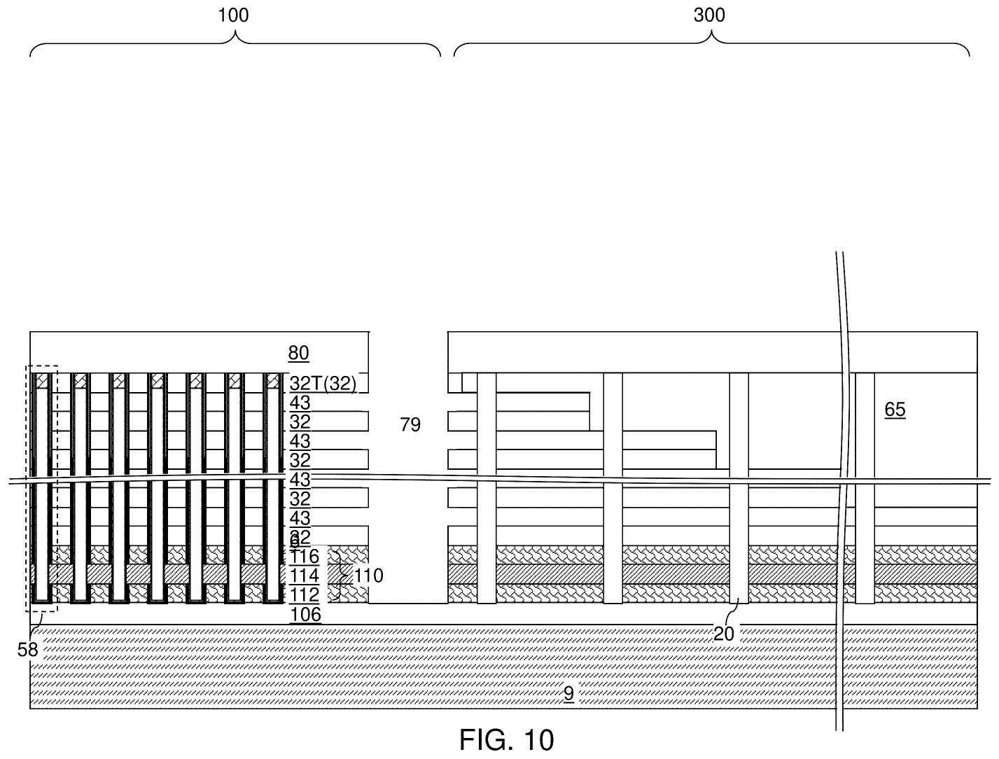

Referring to FIG. 8, an etchant that etches the material of the source-level sacrificial layer 104 selective to the materials of the alternating stack (32, 42), the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Referring to FIG. 9, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

Referring to FIG. 10, an isotropic etch process can be performed to remove the sacrificial material layers 42 selective to the insulating layers 32, the stopper insulating layer 106, the memory opening fill structures 58, the sacrificial etch stop liners 71, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary structure is immersed in phosphoric acid at or near the boiling point of the phosphoric acid. A suitable clean process may be performed as needed. In summary, the laterally-extending cavities 43 can be formed by removing the sacrificial material layers 42 selective to the insulating layers 32 and the memory opening fill structures 58.

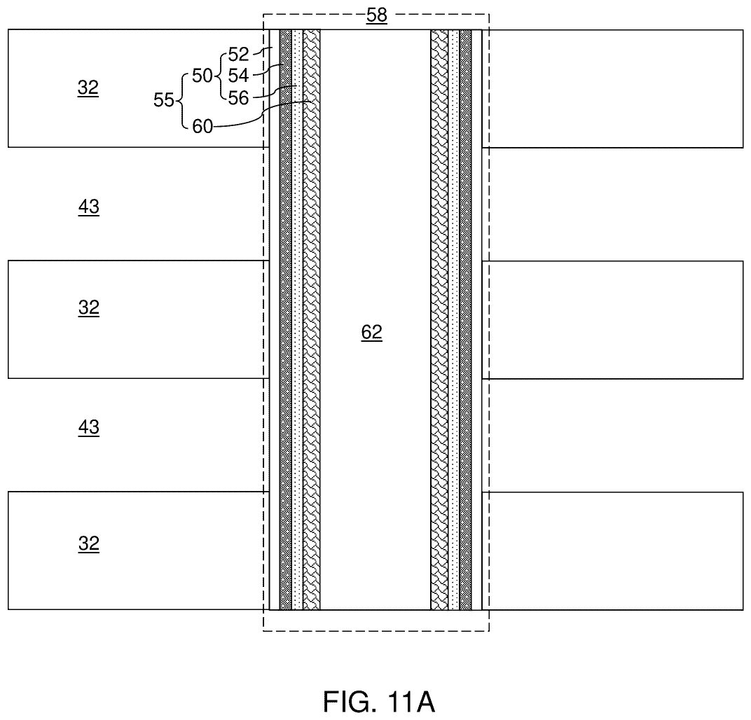

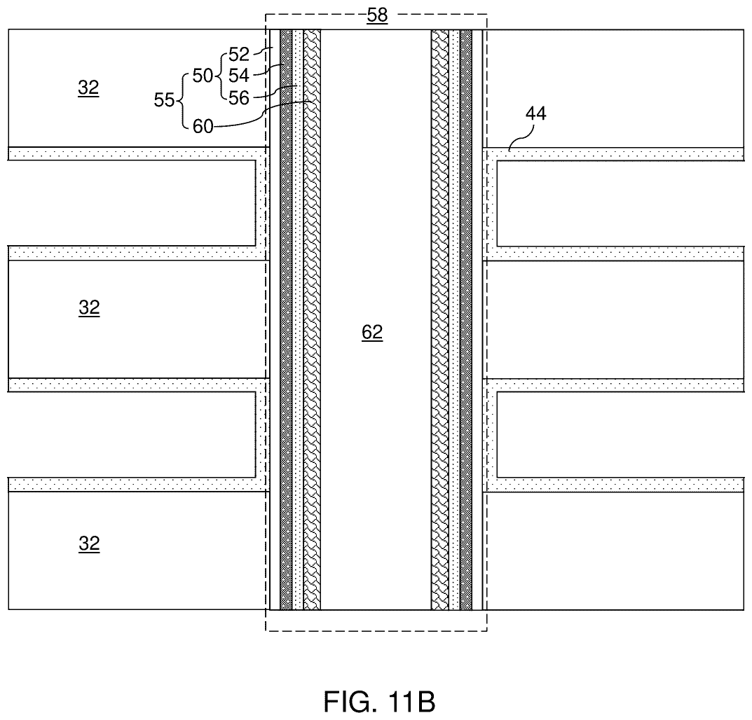

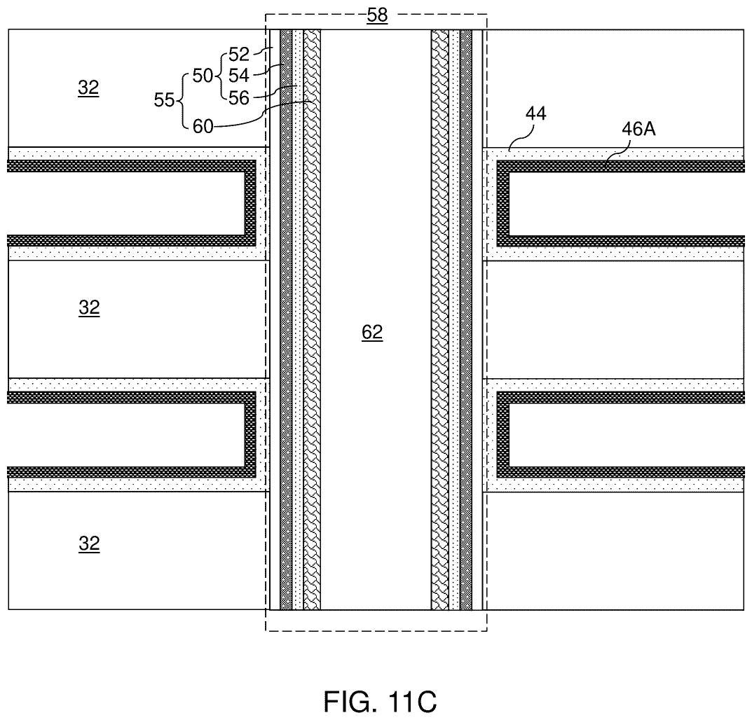

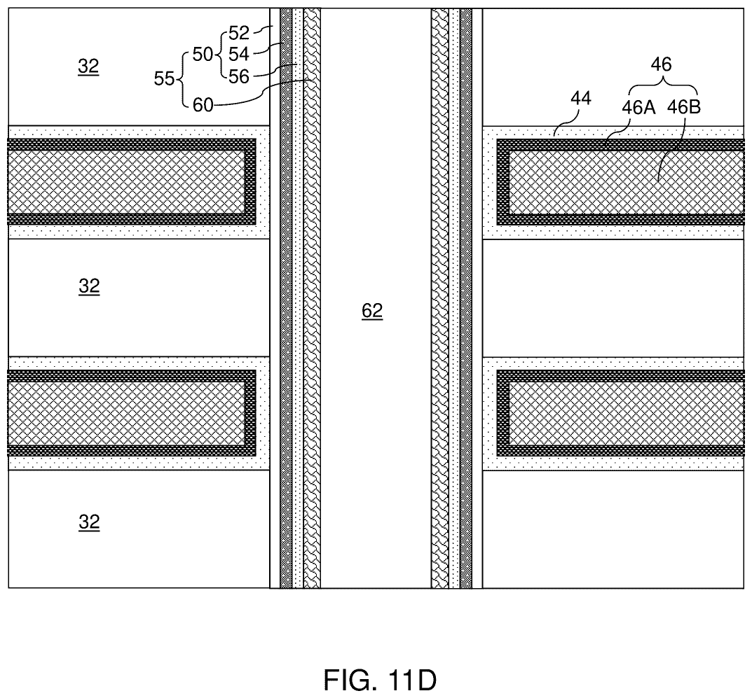

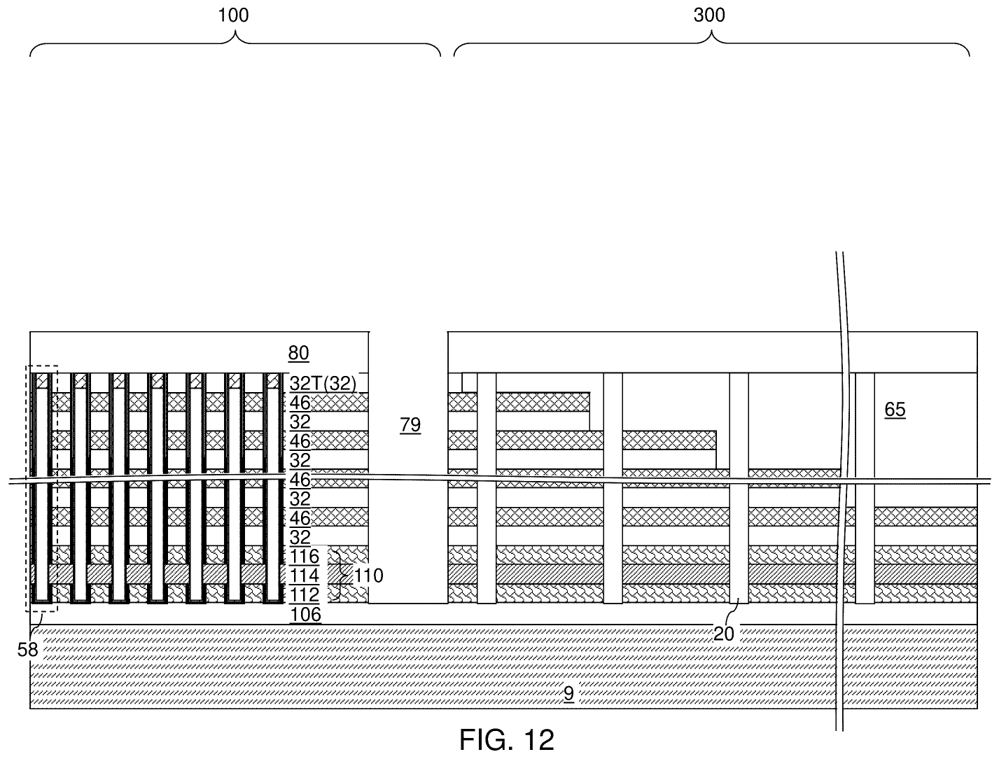

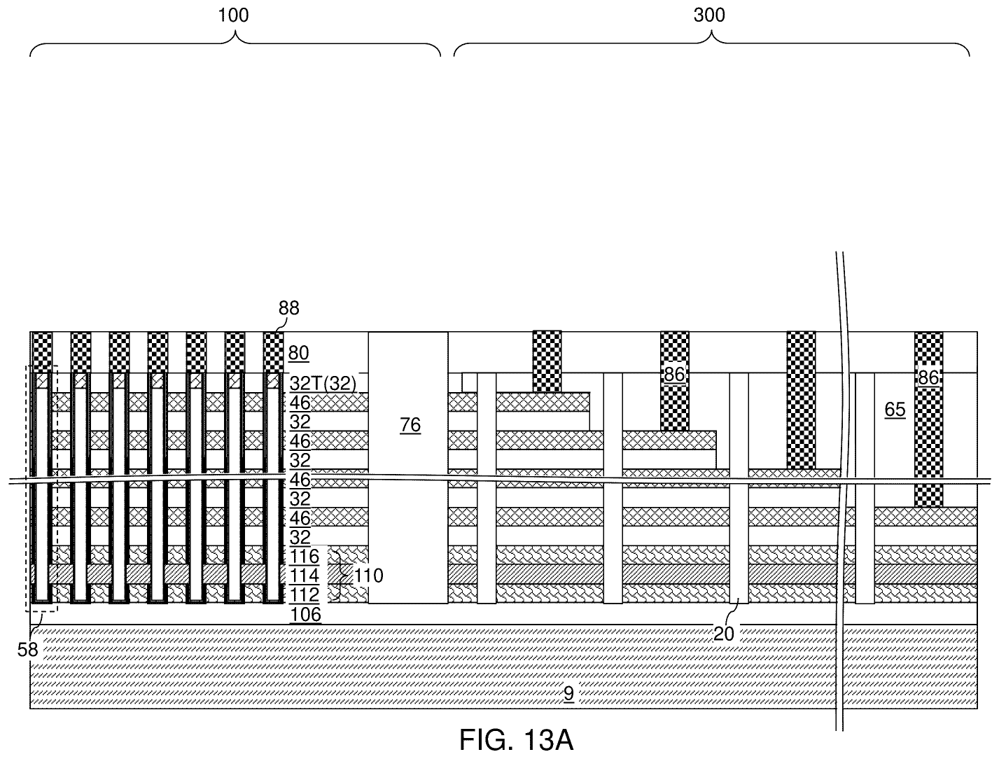

FIGS. 11A-11E are sequential vertical cross-sectional views of a region of the exemplary structure during formation of an outer blocking dielectric layer 44, and an electrically conductive layer 46 in each of the laterally-extending cavities 43 according to an embodiment of the present disclosure.

Referring to FIG. 11A, a region of the exemplary structure is illustrated after the processing steps of FIG. 10. Cylindrical outer surface segments of each memory opening fill structure 58 and horizontally-extending surfaces of the insulating layers 32 can be exposed to the laterally-extending cavities 43.

Referring to FIG. 11B, an outer blocking dielectric layer 44 is deposited in the laterally-extending cavities 43. The outer blocking dielectric layer 44 includes and/or consists essentially of a dielectric metal oxide material, such as aluminum oxide. The outer blocking dielectric layer 44 can be deposited by a conformal deposition process, and may have a uniform thickness throughout. In one embodiment, an atomic layer deposition (ALD) process or a chemical vapor deposition (CVD) process may be employed to deposit the outer blocking dielectric layer 44. The outer blocking dielectric layer 44 may have a thickness in a range from 1 nm to 10 nm, such as from 2 nm to 5 nm, although lesser and greater thicknesses may also be employed. The outer blocking dielectric layer 44 can be formed directly on sidewall surface segments of the memory opening fill structures 58.

Referring to FIG. 11C, an electrically conductive tungsten nitride containing diffusion barrier layer 46A can be conformally deposited on the physically exposed surfaces of the outer blocking dielectric layer 44. The tungsten nitride containing diffusion barrier layer 46A may consist essentially of tungsten nitride or may comprise doped tungsten nitride, such as boron doped tungsten nitride (e.g., tungsten boronitride).

In one embodiment, the tungsten nitride containing diffusion barrier layer 46A may comprise and/or may consist essentially of stoichiometric tungsten nitride in which the atomic ratio between tungsten atoms and nitrogen atoms is 1:1. Alternatively, the tungsten nitride containing diffusion barrier layer 46A may comprise other atoms, such as boron atoms at an atomic percentage in a range from 1% to 40%, such as from 5% to 33%, although lesser and greater atomic percentages may also be employed. The tungsten nitride containing diffusion barrier layer 46A may be deposited by a conformal deposition process such as an atomic layer deposition process or a chemical vapor deposition process. The thickness of the tungsten nitride containing diffusion barrier layer 46A may be in a range from 1 nm to 8 nm, such as from 2 nm to 5 nm, although lesser and greater thicknesses may also be employed.

Referring to FIG. 11D, a metal layer 46B including a metal at an atomic percentage greater than 95%, and/or greater than 99%, and/or greater than 99.8%, may be deposited in remaining volumes of the laterally-extending cavities 43. In one embodiment, the metal may comprise tungsten, molybdenum, ruthenium or cobalt. The metal layer 46B may be deposited by a conformal deposition process such as a chemical vapor deposition process, and can fill remaining volumes of the laterally-extending cavities 43. In one embodiment, the metal layer 46B comprises tungsten deposited on the tungsten nitride containing diffusion barrier layer 46A by a two-step process including forming a silicon or boron containing nucleation layer using a first B₂H₆ or silane (SiH₄) gas pre-treatment step followed by depositing a tungsten layer using tungsten hexafluoride or another suitable tungsten precursor in a second step. The tungsten precursor gas may optional also be provided during the first step.

An anisotropic etch process can be performed to remove portions of the metal layer 46B and the tungsten nitride containing diffusion barrier layer 46A and optionally the outer blocking dielectric layer 44 from inside the volumes of the lateral isolation trenches 79 and from above the contact-level dielectric layer 80. Each contiguous remaining portion of the combination of the metal layer 46B and the tungsten nitride containing diffusion barrier layer 46A located within a volume of a respective laterally-extending cavity 43 constitutes an electrically conductive layer 46. Each electrically conductive layer 46 can be laterally spaced from the memory opening fill structures 58, a respective overlying one of the insulating layers 32, and a respective underlying one of the insulating layers 32 by the outer blocking dielectric layer 44.

Alternating stacks (32, 46) of insulating layers 32 and electrically conductive layers 46 is thus formed. The alternating stacks (32, 46) of insulating layers 32 and electrically conductive layers 46 can be laterally spaced apart from each other along the second horizontal direction hd2 by the lateral isolation trenches 79. The outer blocking dielectric layer 44 may be divided into multiple outer blocking dielectric layers 44 located within a respective one of the laterally-extending cavities 43 during an etch back process that removes portions of the combination of the metal layer 46B and the tungsten nitride containing diffusion barrier layer 46A located in the lateral isolation trenches 79, or may remain as a single contiguous outer blocking dielectric layer 44.

Referring to FIG. 12, the exemplary structure is illustrated after the processing steps of FIG. 11D. While the outer blocking dielectric layer(s) 44 is/are not expressly illustrated in FIG. 12 for the purpose clarity, it is understood that the outer blocking dielectric layer(s) 44 may be present in the exemplary structure.

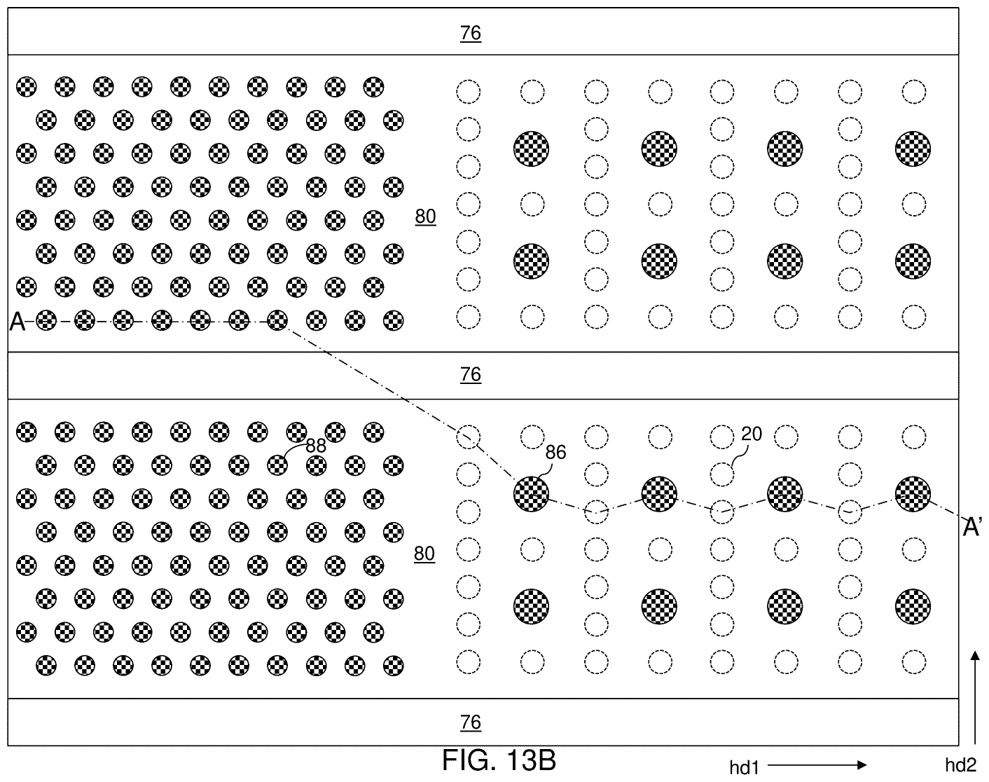

Referring to FIGS. 13A and 13B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer. In summary, an isolation trench fill structure 76 having an insulating sidewall vertically extends from a bottommost surface of an alternating stack (32, 46) to a topmost surface of the alternating stack (32, 46).

A photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

Generally, a contact-level dielectric layer 80 can overlie semiconductor devices (such as memory opening fill structures 58 extending through an alternating stack of insulting layers 32 and electrically conductive layers 46). Contact-level metal structures may be embedded in the contact-level dielectric layer 80 and may be electrically connected to a respective electrical node, such as the drain regions 63, of the semiconductor devices. For example, drain contact via structures 88 can be formed in the contact-level dielectric layer 80 as a subset of the contact-level metal structures.

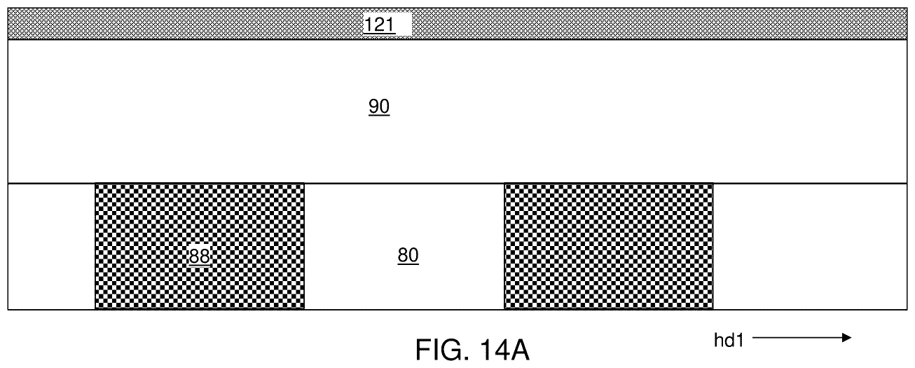

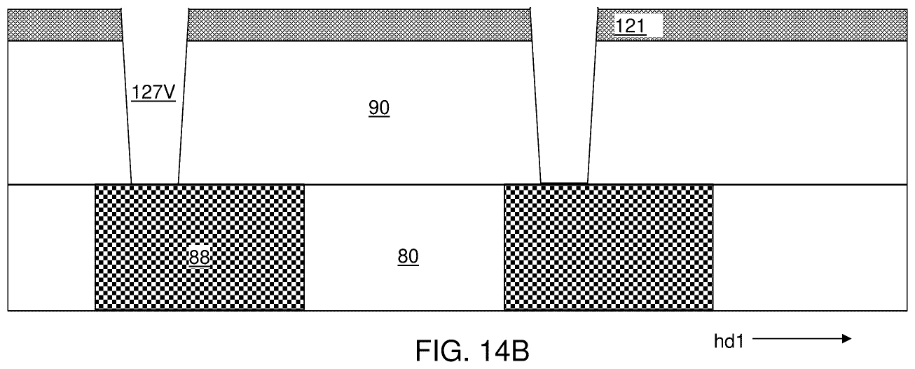

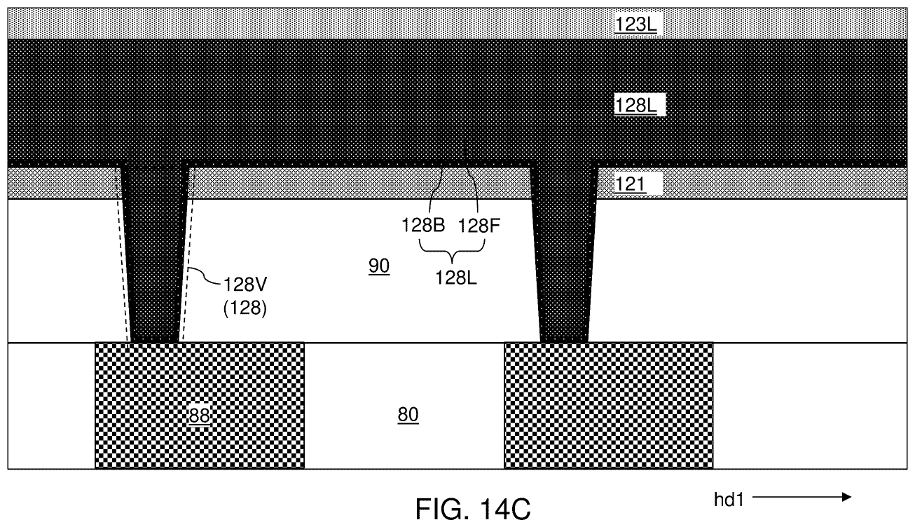

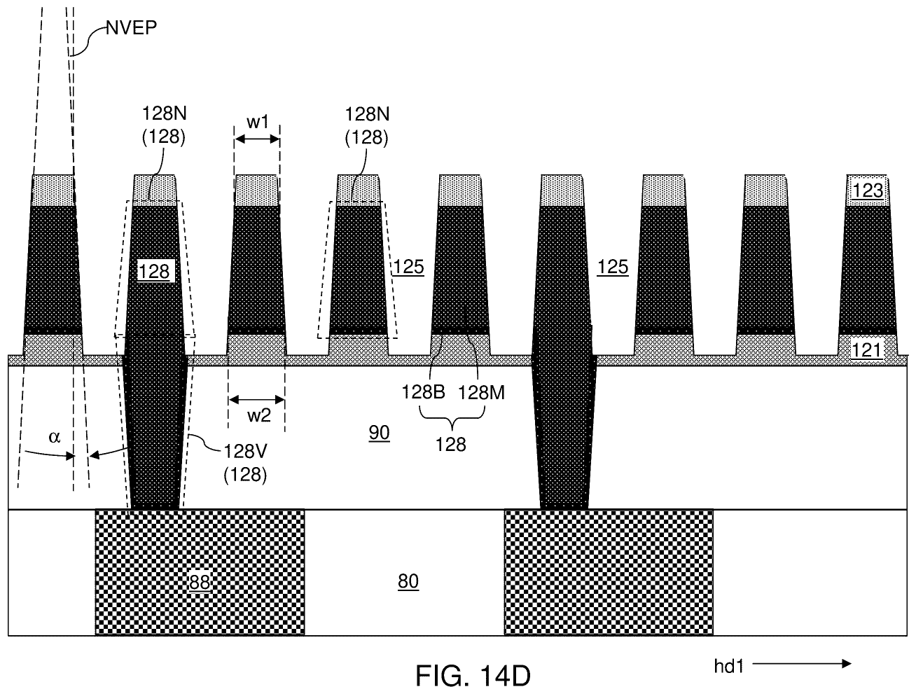

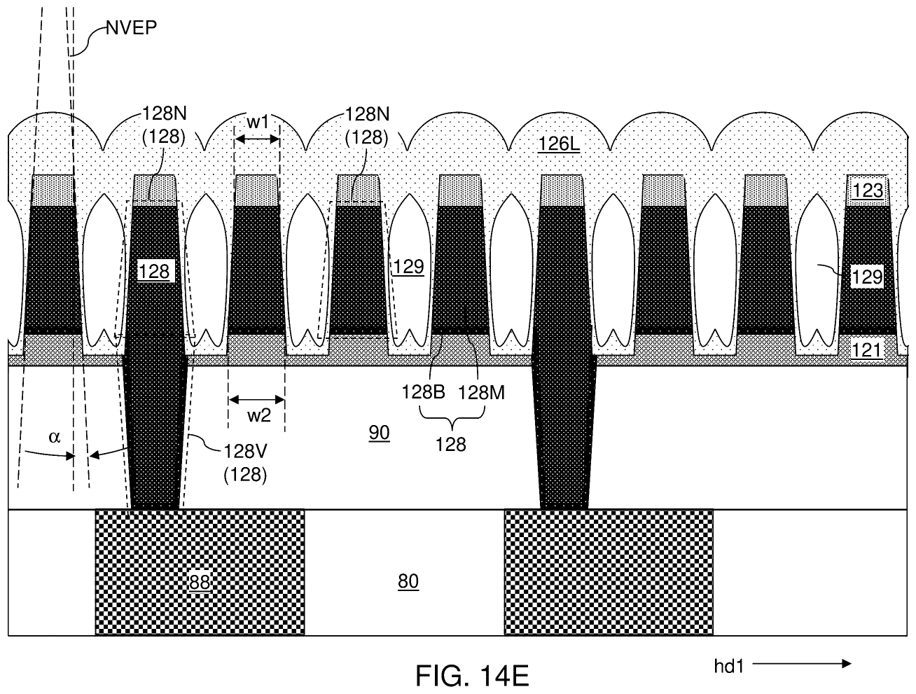

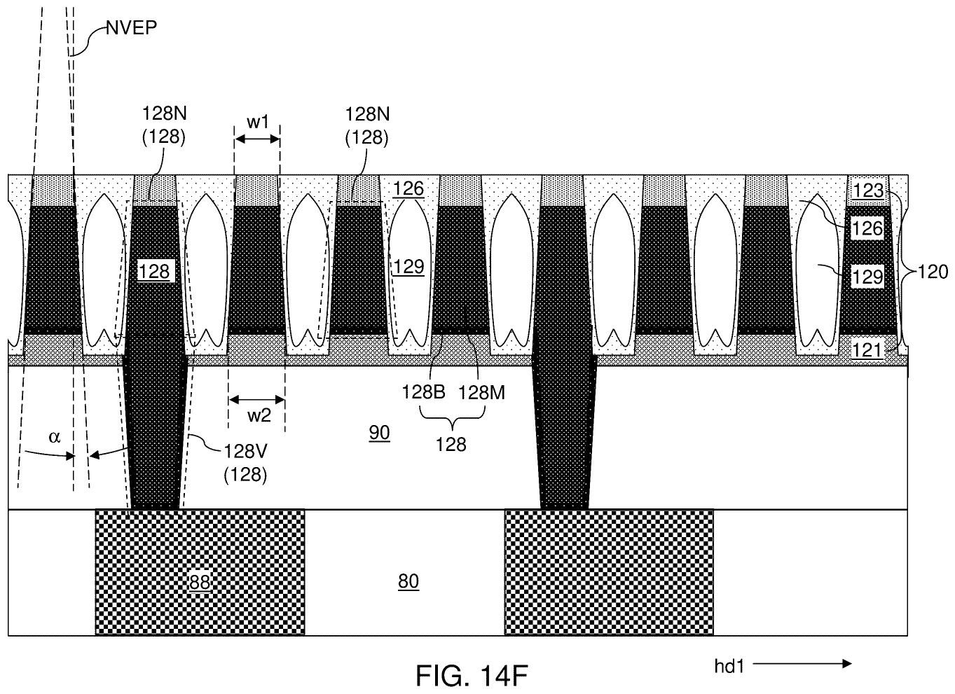

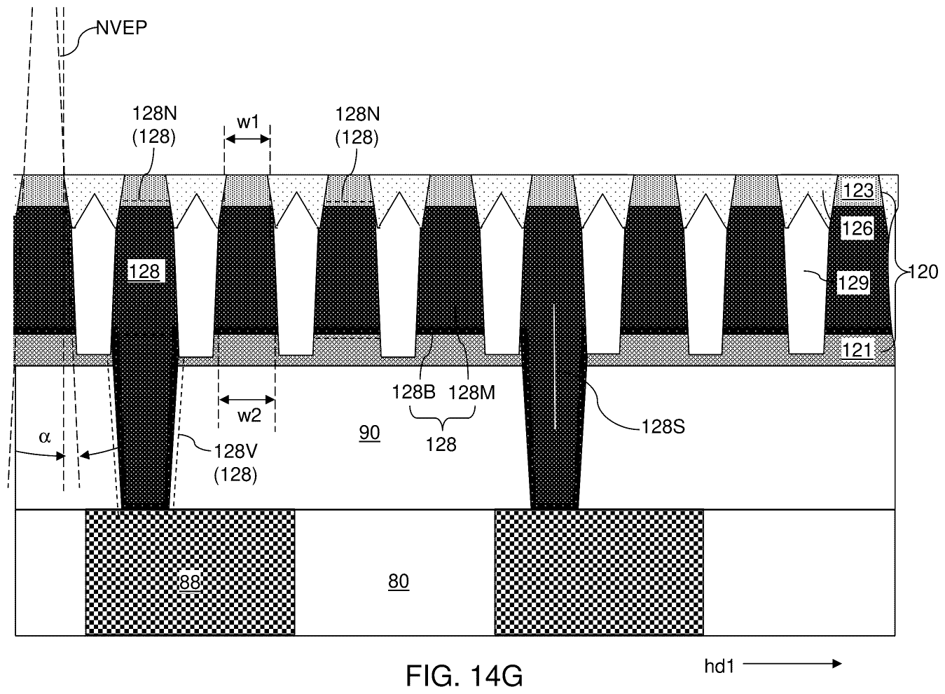

FIGS. 14A-14F are sequential vertical cross-sectional views of a region of a first configuration of the exemplary structure during formation of a via-level dielectric layer (such as a first via-level dielectric layer 90), a composite line-level dielectric layer 120, and integrated line-and-via structures 128 according to a first embodiment of the present disclosure.

Referring to FIG. 14A, a first via-level dielectric layer 90 can be formed over the contact-level dielectric layer 80. The first via-level dielectric layer 90 comprises a dielectric material such as undoped silicate glass (e.g., silicon oxide), a doped silicate glass, or a porous or non-porous organosilicate glass. The first via-level dielectric layer 90 may be deposited by a chemical vapor deposition or by spin coating. The thickness of the first via-level dielectric layer 90 may be in a range from 50 nm to 300 nm, although lesser and greater thicknesses may also be employed.

An etch-stop dielectric layer 121 can be formed over the first via-level dielectric layer 90. The etch-stop dielectric layer 121 comprises an etch-stop dielectric material. such as silicon nitride, silicon carbide nitride (i.e., silicon carbonitride), etc. The thickness of the etch-stop dielectric layer 121 may be in a range from 5 nm to 60 nm, such as from 10 nm to 40 nm, although lesser and greater thicknesses may also be employed.

Referring to FIG. 14B, a photoresist layer (not shown) can be applied over the etch-stop dielectric layer 121, and can be lithographically patterned to form openings in areas that overlie a respective one of the contact-level metal structures (such as the drain contact via structures 88). In one embodiment, an opening can be formed in the photoresist layer per each contact-level metal structure. In one embodiment, the openings in the photoresist layer can be elongated along the second horizontal direction hd2, which can be a bit line direction. In this case, the first horizontal direction hd1 comprises a word line direction for the electrically conductive layers 46. An anisotropic etch process can be performed to transfer the pattern of the openings in the photoresist layer through the etch-stop dielectric layer 121 and the first via-level dielectric layer 90. Via cavities 127V can be formed through the etch-stop dielectric layer 121 and the first via-level dielectric layer 90. A surface segment of a top surface of a respective contact-level metal structure (such as a drain contact via structure 88) can be physically exposed underneath each via cavity 127V. The photoresist layer can be subsequently removed, for example, by ashing.

Referring to FIG. 14C, at least one metallic material layer 128L can be deposited in the via cavities 127V and over the etch-stop dielectric layer 121. In one embodiment, the at least one metallic material layer 128L may comprise a metallic barrier liner 128B and a metallic fill material layer 128F. The metallic barrier liner 128B comprises a metallic diffusion barrier material, such as a conductive metallic nitride material and/or a conductive metallic carbide material. Exemplary materials that may be employed for the metallic barrier liner 128B include TiN, TaN, WN, MON, TiC, TaC, WC, etc. The metallic barrier liner 128B may be deposited by a chemical vapor deposition process or a physical vapor deposition process. The thickness of the metallic barrier liner 128B may be in a range from 3 nm to 30 nm, such as from 6 nm to 15 nm, although lesser and greater thicknesses may also be employed.

The metallic fill material layer 128F comprises a high-electrical-conductivity metal, such as Cu, Al, W, Mo, Co, Ru, Ti, Ta, etc. The thickness of horizontally-extending portions of the metallic fill material layer 128F above the etch-stop dielectric layer 121 may be in a range from 50 nm to 300 nm, although lesser and greater thicknesses may also be employed.

An etch-stop dielectric cap material layer 123L can be formed over the at least one metallic material layer 128L. The etch-stop dielectric cap material layer 123L comprises an etch-stop dielectric material such as silicon nitride, silicon carbide nitride, silicon oxynitride, a dielectric metal oxide, etc. The material of the etch-stop dielectric cap material layer 123L may be the same as, or may be different from, the material of the etch-stop dielectric layer 121. The thickness of the etch-stop dielectric cap material layer 123L may be in a range from 5 nm to 60 nm, such as from 10 nm to 40 nm, although lesser and greater thicknesses may also be employed.

Referring to FIG. 14D, a photoresist layer (not shown) can be applied over the top surface of the etch-stop dielectric cap material layer 123L, and can be lithographically patterned with a line-and-space pattern in an area including an array of contact-level metal structures (such as in the area of the memory array region 100 that includes the array of drain contact via structures 88). In one embodiment, the line-and-space pattern may include line patterns that laterally extend along the second horizontal direction hd2 and laterally spaced apart from each other along the first horizontal direction hd1. The line-and-space pattern may have a uniform pitch along the first horizontal direction hd1. The line-and-space pattern may be aligned to the via cavities 127V (which are now filled with downward-protruding portions of the at least one metallic material layer 128L) such that each of the via cavities 127V is covered with a respective line pattern of the photoresist layer.

The patten in the photoresist layer can be transferred through the etch-stop dielectric cap material layer 123L, the at least one metallic material layer 128L, and into an upper portion of the etch-stop dielectric layer 121 by performing an anisotropic etch process. In one embodiment, the anisotropic etch process may comprise a first anisotropic etch step that etches the material of the etch-stop dielectric cap material layer 123L, a second anisotropic etch step that etches the material(s) of the at least one metallic material layer 128L selective to the material of the etch-stop dielectric layer 121, and a third anisotropic etch step that etches the material of the etch-stop dielectric layer 121. In one embodiment, the duration of the third anisotropic etch step may be selected such that the etch-stop dielectric layer 121 is not etched through.

The etch-stop dielectric cap material layer 123L, the at least one metallic material layer 128L, and an upper portion of the etch-stop dielectric layer 121 can be patterned by the anisotropic etch process. The photoresist layer can be subsequently removed, for example, by ashing. Patterned portions of the at least one metallic material layer 128L comprise integrated line-and-via structures 128 each comprising a metal line portion 128N and at least one via portion 128V. As used herein, an “integrated line-and-via structure” refers to a metallic structure including a horizontally-extending metallic material portion that functions as a metal line portion and at least one vertically-extending metallic material portion that functions as a metal via portion. The via portions 128V of the integrated line-and-via structures 128 are formed below the horizontal plane including the topmost surface of the etch-stop dielectric layer 121, and the metal line portions 128N of the integrated line-and-via structures 128 are formed above the horizontal plane including the topmost surface of the etch-stop dielectric layer 121.

Each via portion 128V of the integrated line-and-via structures 128 vertically extends through the etch-stop dielectric layer 121 and the via-level dielectric layer (such as a first via-level dielectric layer 90) and contacts a top surface of a respective one of the contact-level metal structures (such as drain contact via structures 88). The metal line portions 128N are laterally spaced apart from each other along the first horizontal direction hd1, and laterally extend along the second horizontal direction hd2 (i.e., the bit line direction). Each integrated line-and-via structure 128 may comprise a metallic barrier liner 128B, which is a patterned portion of the metallic barrier liner 128B as formed at the processing steps of FIG. 14C. Each integrated line-and-via structure 128 may further comprise a metallic fill material portion 128M, which is a patterned portion of the metallic fill material layer 128F as formed at the processing steps of FIG. 14C. In one embodiment, each metallic barrier liner 128B may comprise and/or may consist essentially of a conductive metal nitride material, and each metal fill material portion 128M may comprise and/or may consist essentially of an elemental metal or an alloy of two or more metals.

Patterned portions of the etch-stop dielectric cap material layer 123L comprise etch-stop dielectric cap rails 123. Each etch-stop dielectric cap rail 123 overlies and contacts a top surface of a respective metal line portion 128N. In one embodiment, the bottom surface of an etch-stop dielectric cap rail 123 may have the same area as a top surface of an underlying metal line portion 128N. As used herein, a “rail” or a “rail structure” refers to a structure that laterally extends along a horizontal direction and having a constant vertical cross-sectional shape in vertical planes that are perpendicular to the horizontal direction. The constant vertical cross-sectional shape is invariant under translation along the horizontal direction. Thus, each metal line portion 128N is a rail structure.

A void is present between each neighboring pair of metal line portions 128N. The voids are herein referred to as inter-line gaps 125, or gaps 125. The etch-stop dielectric layer 121 can be vertically recessed underneath each inter-line gap 125. The thickness of each portion of the etch-stop dielectric layer 121 that underlies a respective inter-line gap 125 may be in a range from 1% to 90%, such as from 10% to 70%, of the thickness of a portion of the etch-stop dielectric layer 121 that underlies a metal line portion 128N.

In one embodiment, at least one of the metal line portions 128N may comprise a pair of tapered electrically conductive sidewalls that are contained within a pair of non-vertical Euclidean planes NVEP that laterally extend along the second horizontal direction hd2. Each non-vertical Euclidean plane NVEP may be tilted relative to a vertical plane that is perpendicular to the first horizontal direction hd1 by a tilt angle a. The tilt angle a may be in a range from 0.1 degree to 6 degrees, and/or from 0.3 degree to 3 degrees, although lesser and greater tilt angles a may also be employed. In one embodiment, at least one of the etch-stop dielectric cap rails 123 contacts a top surface of a respective one of the metal line portions 128N, and comprises a respective pair of tapered dielectric sidewalls that are contained within a respective pair of non-vertical Euclidean planes NVEP.

In one embodiment, at least one of the metal line portions 128N may have a respective top surface having a first width w1 along the first horizontal direction hd1, and may have a respective bottom surface having a second width w2 along the first horizontal direction hd1 and contacting a top surface of the etch-stop dielectric layer 121. The second width w2 is greater than the first width w1.

Referring to FIG. 14E, a dielectric material can be anisotropically deposited in peripheral portions of the inter-line gaps 125 and over the etch-stop dielectric cap rails 123 to form a dielectric material layer 126L, which is also referred to as a cavity-containing dielectric material layer. The dielectric material is deposited employing a highly-direction deposition method that deposits the dielectric material along vertical and near-vertical downward directions. For example, a plasma-enhanced chemical vapor deposition process may be employed to deposit the dielectric material layer 126L. The dielectric material layer 126L may comprise, for example, low dielectric constant (low-k) organosilicate glass, silicon carbide or silicon oxycarbide. The low-k organosilicate glass has a dielectric constant of less than 3.9.

The duration of the deposition process that deposits the dielectric material layer 126L may be selected such that dielectric material portions that grow from the top surfaces and sidewalls of the etch-stop dielectric cap rails 123 merge to form a continuous horizontally-extending dielectric material portion that overlies an entirety of the inter-line gaps 125. An air gap (i.e., an encapsulated cavity) 129 that is free of any solid phase material can be formed in each volume of an inter-line gap 125. Each air gap 129 may be under vacuum or may be filled with a gas phase material. In one embodiment, at least one of the air gaps 129 may have a respective vertical cross-sectional profile along a vertical plane that is perpendicular to the second horizontal direction hd2. The respective vertical cross-sectional profile may have a pointed tip portion having a decreasing width as a function of an increasing distance from a horizontal plane including a bottom surface of the etch-stop dielectric layer 121. The pointed tip portion may be the topmost portion of the respective air gap 129. The respective vertical cross-sectional profile may have an upward protrusion at a bottom end, which may be caused by direction deposition of the material of the dielectric material layer 126L.

In one embodiment, the dielectric material layer 126L may have a portion deposited on the upper surface of the etch-stop dielectric layer 121. In this embodiment, the dielectric material layer 126L may entirely surround the air gap 129. In an alternative embodiment, the dielectric material layer 126L may not have any portions deposited on the upper surface of the etch-stop dielectric layer 121. In this embodiment, the upper surface of the etch-stop dielectric layer 121 is exposed in the air gap 129.

Referring to FIG. 14F, a chemical mechanical polishing (CMP) process can be performed to remove portions of the dielectric material layer 126L that are located above the horizontal plane including the top surfaces of the etch-stop dielectric cap rails 123. Each remaining portion of the dielectric material layer 126L located within the volume of a respective inter-line gap 125 constitutes a dielectric rail 126. The dielectric rails 126 are formed between neighboring pairs of metal line portions 128N. In one embodiment, the dielectric rails 126 have planar top surfaces that are contained within a horizontal plane including top surfaces of the etch-stop dielectric cap rails 123. In summary, the dielectric rails 126 may be formed by anisotropically depositing a dielectric material into the gaps 125 between the metal line portions 128N of the integrated line-and-via structures 128, and by removing portions of the dielectric material from above a horizontal plane including top surfaces of the metal line portions 128N. The combination of the etch-stop dielectric layer 121, the etch-stop dielectric cap rails 123, and the dielectric rails 126, and the air gaps 129 constitutes a composite line-level dielectric layer 120. The respective air gaps 129 are located between neighboring pairs of the metal line portions 128N.

In one embodiment in which the dielectric material layer 126L entirely surrounds the air gap 129, each dielectric rails 126 contains a respective air gap 129 therein, as shown in FIG. 14F. Each of the air gaps 129 is located entirely within a respective one of the dielectric rails 126. In this embodiment, the entirety of surfaces of at least one of the air gaps 129 may consist of inner dielectric surfaces of a respective one of the dielectric rails 126. Thus, each of the air gaps 129 are completely enclosed by a respective one of the dielectric rails 126. In this embodiment, at least one of the dielectric rails 126 comprises: a respective bottom surface contacting a respective recessed horizontal surface of the etch-stop dielectric layer 121; a respective pair of lower tapered sidewalls contacting respective sidewalls of the etch-stop dielectric layer 121; and a pair of upper tapered sidewalls contacting sidewalls of a respective pair of metal line portions 128N of the integrated line-and-via structures 128.

In the alternative embodiment in which the upper surface of the etch-stop dielectric layer 121 is exposed in the air gap 129, each dielectric rails 126 is located over a respective air gap 129, as shown in FIG. 14G. Each of the air gaps 129 is located entirely below a respective one of the dielectric rails 126. In this embodiment, the surfaces of at least one of the air gaps 129 include a lower dielectric surface of a respective one of the dielectric rails 126 and an upper dielectric surface of the etch-stop dielectric layer 121. If the sidewalls of the neighboring pairs of the metal line portions 128N are exposed in at least one of the air gaps 129, then such sidewalls also form part of the surface of at least one of the air gaps 129. Thus, each of the air gaps 129 are partially enclosed by a respective one of the dielectric rails 126.

In one embodiment, at least one of the integrated line-and-via structures 128 may comprise a respective metallic barrier liner 128B comprising a conductive metal nitride material and a respective metal fill material portion 128M. In one embodiment, interfaces between at least one of the integrated line-and-via structures 128 and a respective pair of dielectric rails 126 may comprise interfaces between a respective metal fill material portion 128M and a respective pair of dielectric rails 126. In one embodiment, at least one of the metallic barrier liners 128B may contact lower portions of sidewalls of a respective pair of dielectric rails 126. In one embodiment, at least one of the integrated line-and-via structures 128 may have an optional vertical seam 128S due to deposition of the integrated line-and-via structures 128 into the via cavities 127V.

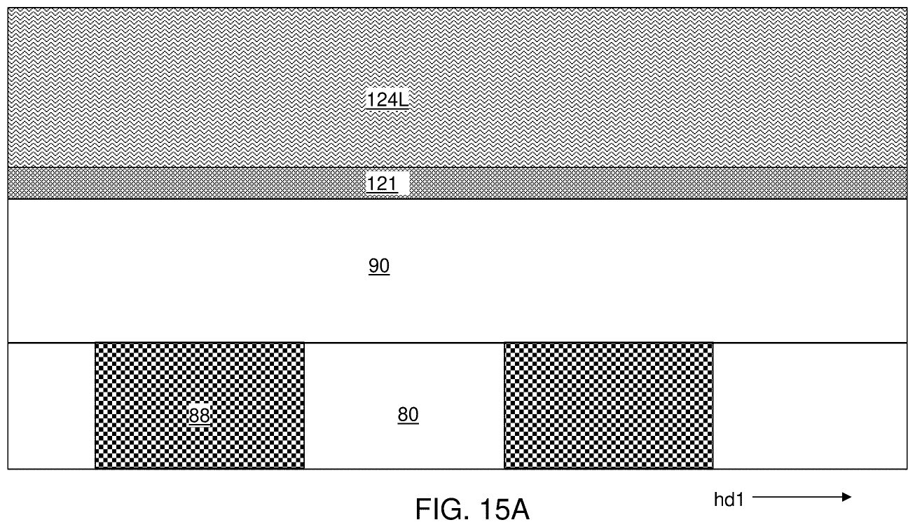

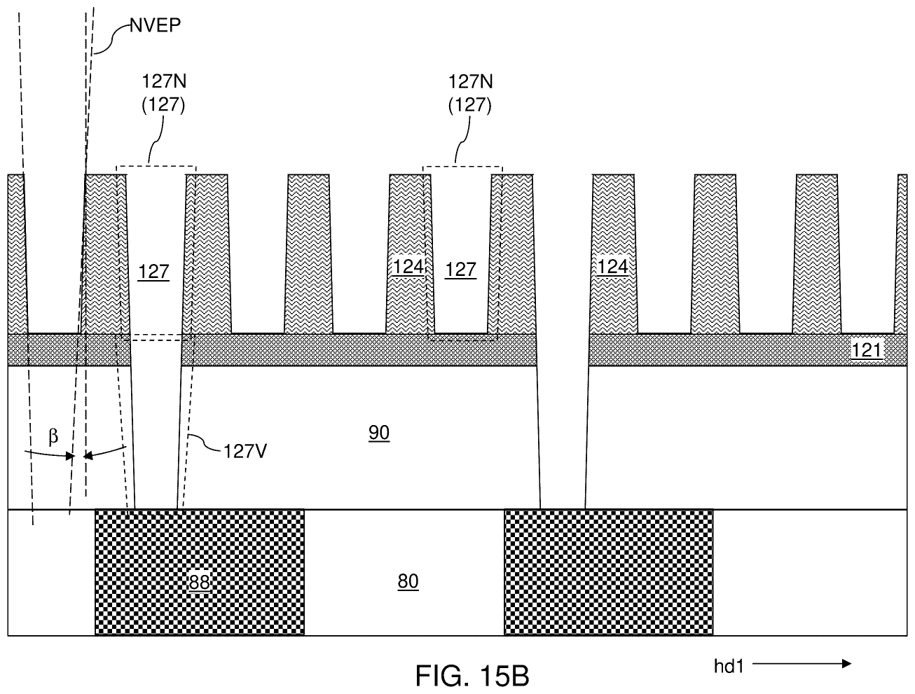

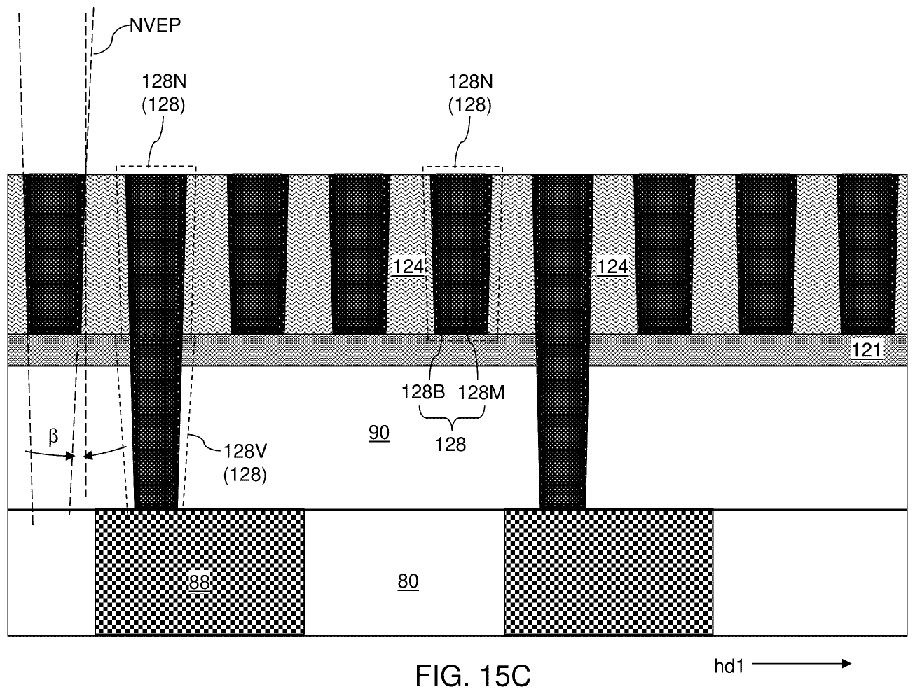

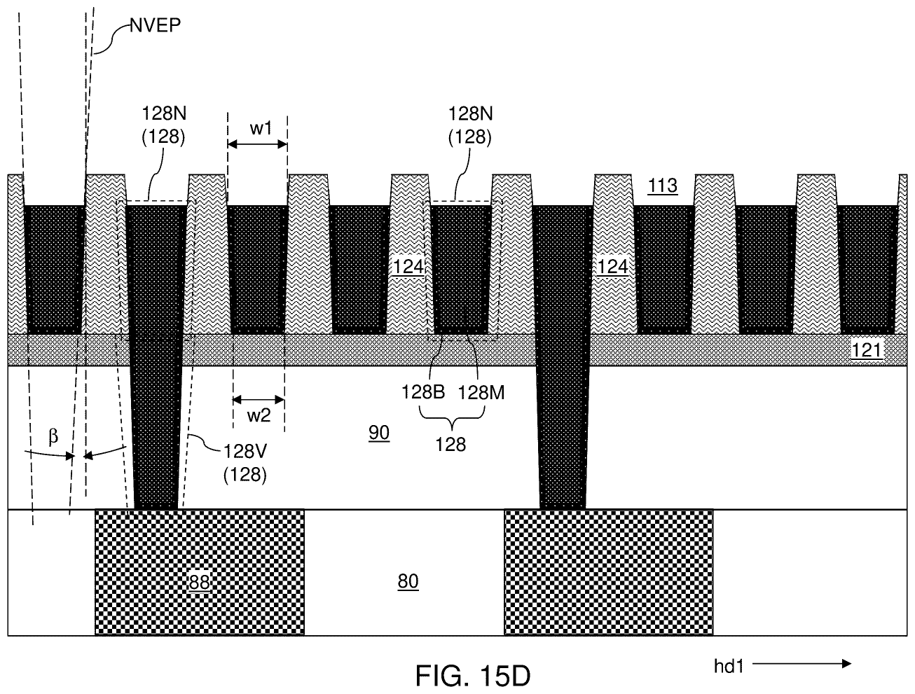

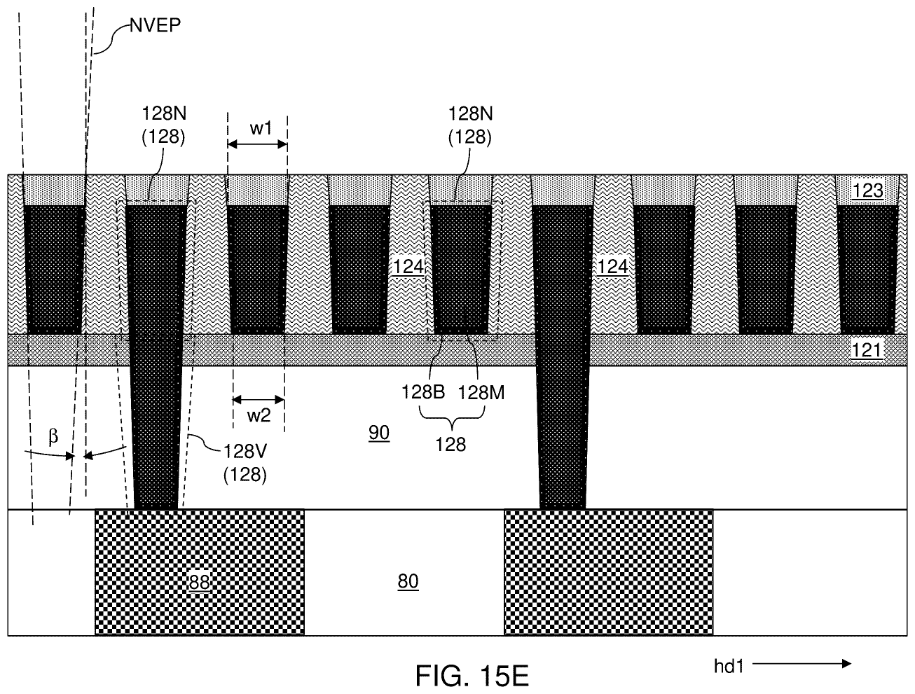

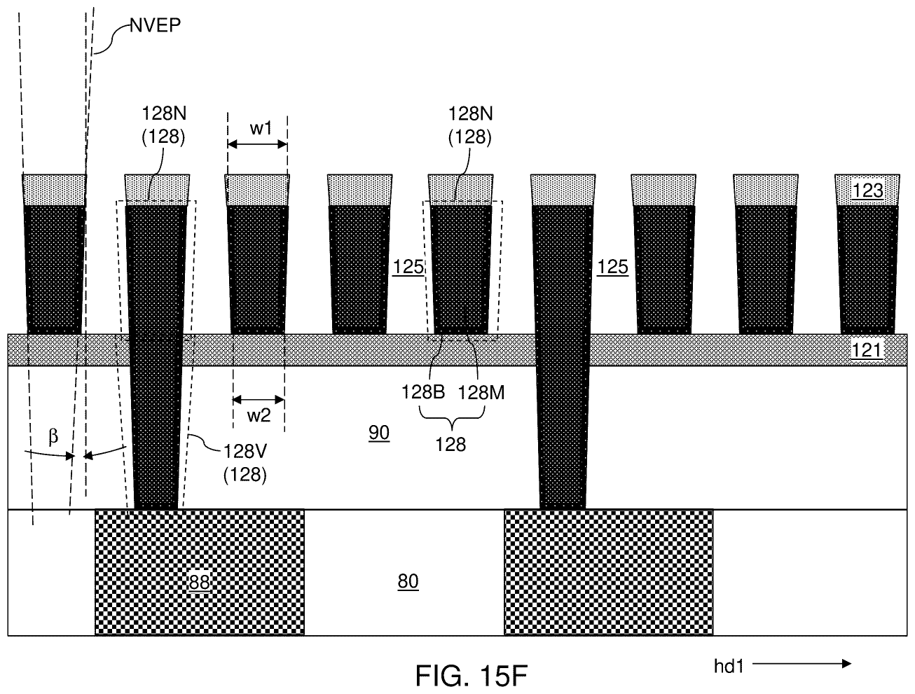

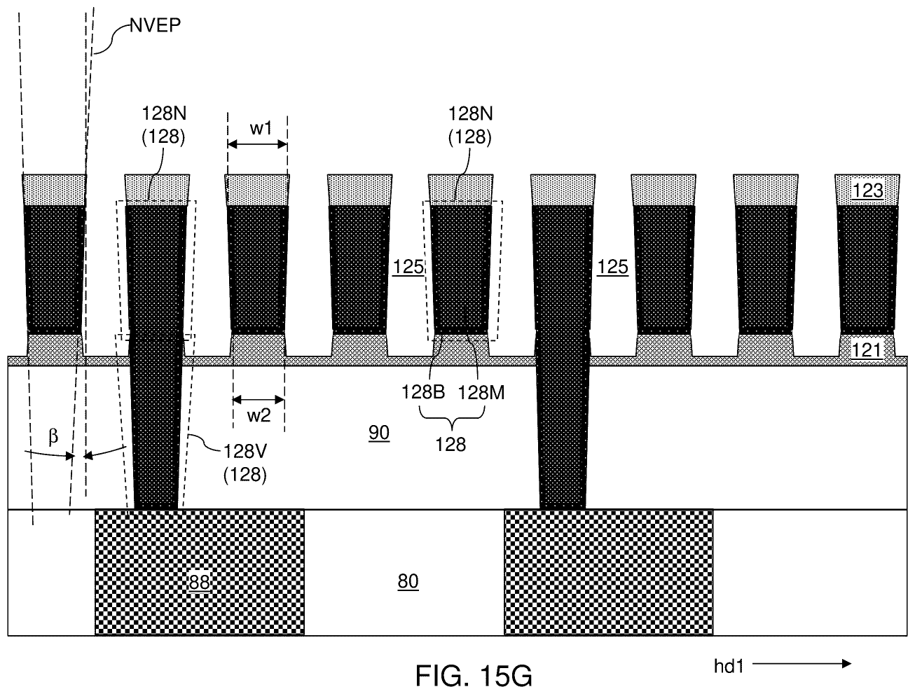

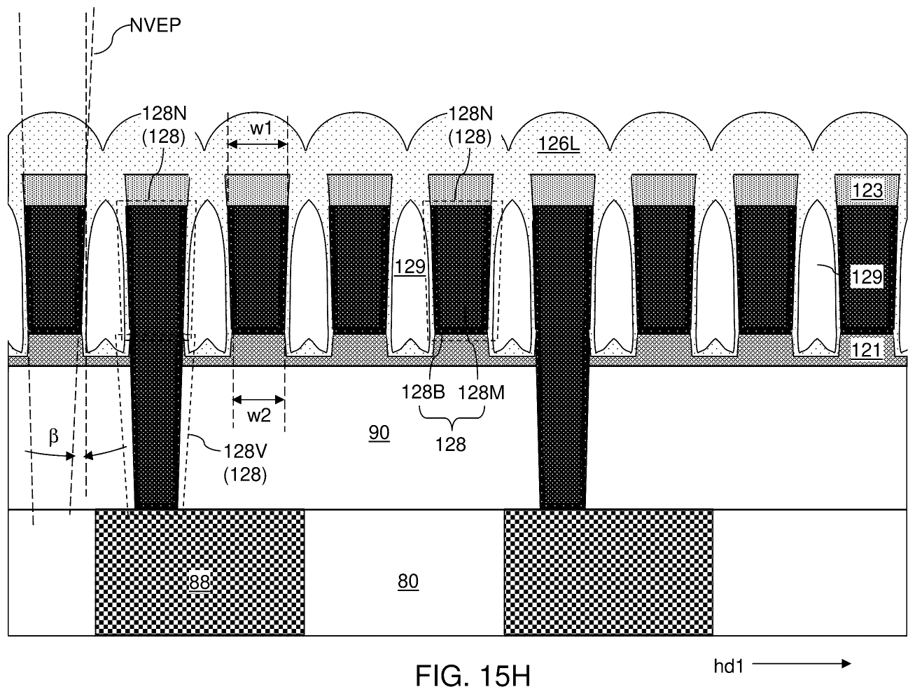

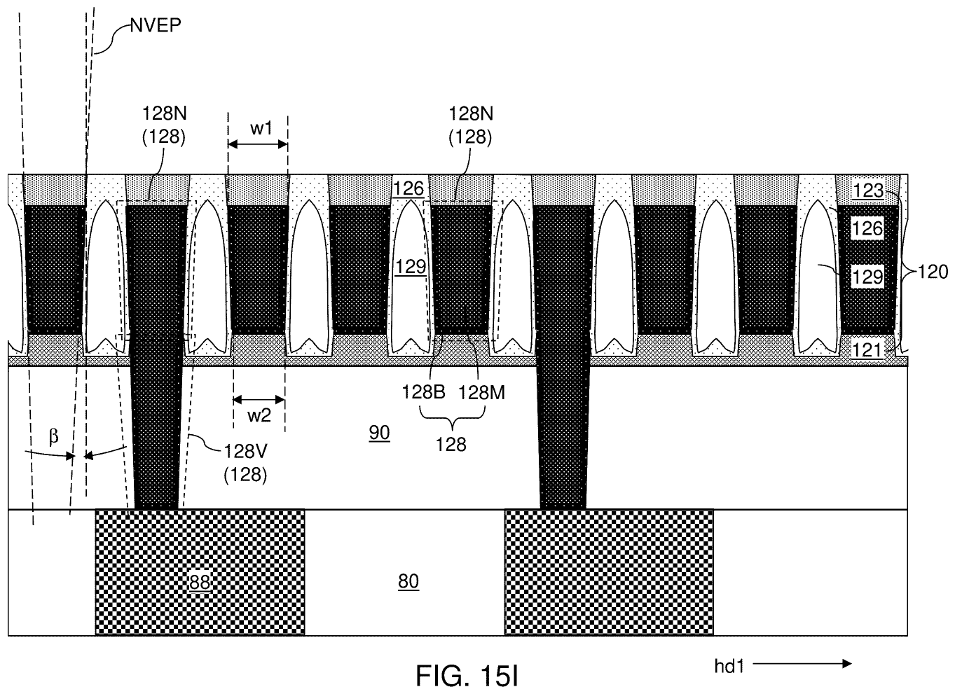

FIGS. 15A-15I are sequential vertical cross-sectional views of a region of a second configuration of the exemplary structure during formation of a via-level dielectric layer (such as a first via-level dielectric layer 90), a composite line-level dielectric layer 120, and integrated line-and-via structures 128 according to a second embodiment of the present disclosure. The processing steps of FIGS. 15A-15I may be performed in lieu of the processing steps of FIGS. 14A-14E.

Referring to FIG. 15A, the second configuration of the exemplary structure can be derived from the first configuration of the exemplary structure illustrated in FIG. 14A by forming a sacrificial template material layer 124L over the etch-stop dielectric layer 121. The sacrificial template material layer 124L comprises a material that can be subsequently removed selective to the material of the etch-stop dielectric layer 121 by a selective removal process. In one embodiment, the sacrificial template material layer 124L may comprise a semiconductor material (such as amorphous silicon or polysilicon), a carbon-based material including carbon at an atomic percentage greater than 80% (such as amorphous carbon, diamond-like carbon, or doped carbon), borosilicate glass, or organosilicate glass. The sacrificial template material layer 124L may be deposited by chemical vapor deposition or by spin-coating. The sacrificial template material layer 124L may have a thickness in a range from 50 nm to 300 nm, although lesser and greater thicknesses may also be employed.

Referring to FIG. 15B, a dual damascene patterning process can be performed to pattern integrated line-and-via cavities 127 through the sacrificial template material layer 124L, the etch-stop dielectric layer 121, and the first via-level dielectric layer 90. In an illustrative example, a first photoresist layer (not shown) can be applied over the sacrificial template material layer 124L, and can be lithographically patterned with a pattern of discrete openings. The pattern of discrete openings may be the same in a plan view as the pattern of the via cavities 127V described with reference to FIG. 14B. Thus, each opening in the first photoresist layer may have an areal overlap with a portion of a respective underlying contact-level metallic structure (such as a respective drain contact via structure 88). A first anisotropic etch process can be performed to transfer the pattern of the openings in the first photoresist layer through the sacrificial template material layer 124L and the etch-stop dielectric layer 121 and optionally into an upper portion of the first via-level dielectric layer 90. The first photoresist layer can be subsequently removed, for example, by ashing.

A second photoresist layer can be applied over the sacrificial template material layer 124L, and can be lithographically patterned with a line-and-space pattern in an area including an array of contact-level metal structures (such as a memory array region 100 that includes an array of drain contact via structures 88). In one embodiment, the line-and-space pattern may include line patterns that laterally extend along the second horizontal direction hd2 and laterally spaced apart from each other along the first horizontal direction hd1. The line-and-space pattern may have a uniform pitch along the first horizontal direction hd1. The line-and-space pattern may be aligned to underlying pre-existing pattern of the via cavities in the sacrificial template material layer 124L and the etch-stop dielectric layer 121 such that each of the pre-existing via cavities underlies a respective gap in the line patterns, i.e., underlies a respective space pattern within the line-and-space pattern.

The patten in the second photoresist layer can be transferred through the sacrificial template material layer 124L and through unmasked portions of the first via-level dielectric layer 90 underlying the pre-existing via cavities by performing a second anisotropic etch process. The second anisotropic etch process may sequentially or simultaneously etch the materials of the sacrificial template material layer 124L and the first via-level dielectric layer 90 selective to the materials of the etch-stop dielectric layer 121 and the contact-level metallic structures (such as the drain contact via structures 88).

Integrated line-and-via cavities 127 can be formed within the combination of the sacrificial template material layer 124L, the etch-stop dielectric layer 121, and the first via-level dielectric layer 90. As used herein, an “integrated line-and-via cavity” refers to a continuous cavity including a horizontally-extending cavity (i.e., a line cavity) and at least one vertically-extending cavity (i.e., at least one via cavity). In this case, each of the integrated line-and-via cavities 127 comprises a respective line cavity 127N that is formed through the sacrificial template material layer 124L and at least one via cavity 127V that is formed through the etch-stop dielectric layer 121 and the first via-level dielectric layer 90. A top surface of a respective underlying contact-level metallic structure (such as a drain contact via structure 88) can be physically exposed underneath each via cavity 127V. Generally, the via cavities 127V of the integrated line-and-via cavities 127 are formed below the horizontal plane including the topmost surface of the etch-stop dielectric layer 121, and the line cavities 127N of the integrated line-and-via structures 128 are formed above the horizontal plane including the topmost surface of the etch-stop dielectric layer 121. The second photoresist layer can be subsequently removed, for example, by ashing.

Patterned portions of the sacrificial template material layer 124L comprise sacrificial template material rails 124. The sacrificial template material rails 124 may have the same pattern in a plan view (such as a top-down view) as the inter-line gaps 125 in the first configuration of the exemplary structure. In one embodiment, at least one of the line cavities 127N may comprise a pair of tapered metallic sidewalls that are contained within a pair of non-vertical Euclidean planes NVEP that laterally extend along the second horizontal direction hd2. Each non-vertical Euclidean plane NVEP may be tilted relative to a vertical plane that is perpendicular to the first horizontal direction hd1 by a tilt angle b. The tilt angle b may be in a range from 0.1 degree to 6 degrees, and/or from 0.3 degree to 3 degrees, although lesser and greater tilt angles b may also be employed.

Referring to FIG. 15C, at least one metallic material layer can be conformally deposited in the integrated line-and-via cavities 127 and over the sacrificial template material rails 124. In one embodiment, the at least one metallic material layer may comprise a metallic barrier liner 128B and a metallic fill material layer 128M as described above with respect to the first embodiment. The thickness of horizontally-extending portions of the metallic fill material layer can be selected such that each of the integrated line-and-via cavities 127 may be filled with the combination of the metallic barrier liner 128B and the metallic fill material layer 128.

A planarization process, such as a chemical mechanical polishing process, can be performed to remove portions of the metallic barrier liner 128B and the metallic fill material layer 128M that overlie the horizontal plane including the top surfaces of the sacrificial template material rails 124. Each remaining continuous portion of the combination of the metallic barrier liner 128B and the metallic fill material layer 128M constitutes an integrated line-and-via structure 128. Each integrated line-and-via structure 128 comprises a metal line portion 128N and at least one via portion 128V. The via portions 128V of the integrated line-and-via structures 128 are formed below the horizontal plane including the topmost surface of the etch-stop dielectric layer 121, and the metal line portions 128N of the integrated line-and-via structures 128 are formed above the horizontal plane including the topmost surface of the etch-stop dielectric layer 121.

Each via portion 128V of the integrated line-and-via structures 128 vertically extends through the etch-stop dielectric layer 121 and the via-level dielectric layer (such as a first via-level dielectric layer 90) and contacts a top surface of a respective one of the contact-level metal structures (such as drain contact via structures 88). The metal line portions 128N are laterally spaced apart from each other along the first horizontal direction hd1, and laterally extend along the second horizontal direction hd2. Each integrated line-and-via structure 128 may comprise a metallic barrier liner 128B and a metallic fill material portion 128M, which is a patterned portion of the metallic fill material layer 128M. In one embodiment, each metallic barrier liner 128B may comprise and/or may consist essentially of a conductive metal nitride material, and each metal fill material portion 128M may comprise and/or may consist essentially of an elemental metal or an alloy of two or more metals.

A sacrificial template material rail 124 is present between each neighboring pair of metal line portions 128N. In one embodiment, at least one of the metal line portions 128N may comprise a pair of tapered electrically conductive sidewalls that are contained within a pair of non-vertical Euclidean planes NVEP that laterally extend along the second horizontal direction hd2. Each non-vertical Euclidean plane NVEP may be tilted relative to a vertical plane that is perpendicular to the first horizontal direction hd1 by the tilt angle b.

Referring to FIG. 15D, a selective etch process can be performed to recess the metallic material(s) of the integrated line-and-via structures 128 selective to the material of the sacrificial template material rails 124. For example, a wet etch process can be performed to isotropically etch the metallic material(s) of the integrated line-and-via structures 128 without significantly etching the material of the sacrificial template material rails 124. Recess cavities 113 are formed in the volumes from which the material of the integrated line-and-via structures 128 is removed. The depth of the recess cavities 113 may be in a range from 5 nm to 60 nm, such as from 10 nm to 40 nm, although lesser and greater depths may also be employed.

In one embodiment, at least one of the metal line portions 128N may have a respective top surface having a first width w1 along the first horizontal direction hd1, and may have a respective bottom surface having a second width w2 along the first horizontal direction hd1 and contacting a top surface of the etch-stop dielectric layer 121. The second width w2 is less than the first width w1.

Referring to FIG. 15E, an etch-stop dielectric material can be deposited in the recess cavities 113. The etch-stop dielectric material may comprise silicon nitride, silicon carbide nitride, silicon oxynitride, a dielectric metal oxide, etc. The etch-stop dielectric material may be the same as, or may be different from, the material of the etch-stop dielectric layer 121. A chemical mechanical polishing (CMP) process can be performed to remove portions of the etch-stop dielectric material from above the horizontal plane including the top surfaces of the sacrificial template material rails 124. Each remaining portion of the etch-stop dielectric material that fills a respective recess cavity 113 constitutes an etch-stop dielectric cap rail 123. The thickness of the etch-stop dielectric cap rails 123 may be in a range from 5 nm to 60 nm, such as from 10 nm to 40 nm, although lesser and greater thicknesses may also be employed.

In one embodiment, at least one of the metal line portions 128N may comprise a pair of tapered metallic sidewalls that are contained within a pair of non-vertical Euclidean planes NVEP that laterally extend along the second horizontal direction hd2. Each non-vertical Euclidean plane NVEP may be tilted relative to a vertical plane that is perpendicular to the first horizontal direction hd1 by a tilt angle b. The tilt angle b may be in a range from 0.1 degree to 6 degrees, and/or from 0.3 degree to 3 degree, although lesser and greater tilt angles b may also be employed. In one embodiment, at least one of the etch-stop dielectric cap rails 123 contacts a top surface of a respective one of the metal line portions 128N, and comprises a respective pair of tapered dielectric sidewalls that are contained within a respective pair of non-vertical Euclidean planes NVEP.

Referring to FIG. 15F, the sacrificial template material rails 124 (which are remaining portions of the sacrificial template material layer 124L) can be removed selective to the materials of the etch-stop dielectric cap rails 123, the integrated line-and-via structures 128, and the etch-stop dielectric layer 121. In an illustrative example, if the sacrificial template material rails 124 comprise amorphous silicon or polysilicon, a wet etch process employing hot trimethyl-2 hydroxyethyl ammonium hydroxide (“hot TMY”) or tetramethyl ammonium hydroxide (TMAH) may be performed to remove the sacrificial template material rails 124 selective to the etch-stop dielectric cap rails 123, the integrated line-and-via structures 128, and the etch-stop dielectric layer 121. Alternatively, an ashing process may be used if the sacrificial template material rails 124 comprise a carbon material. A void is present between each neighboring pair of metal line portions 128N. The voids are herein referred to as the inter-line gaps 125 (or gaps 125). A top surface segment of the etch-stop dielectric layer 121 can be physically exposed underneath each inter-line gap 125.

Referring to FIG. 15G, an anisotropic etch process may be optionally performed to vertically recess unmasked portions of the etch-stop dielectric layer 121 underneath each inter-line gap 125. If the etch-stop dielectric cap rails 123 comprise the same material as the etch-stop dielectric layer 121, the etch-stop dielectric cap rails 123 may be collaterally recessed vertically. If the etch-stop dielectric cap rails 123 comprise a different material than the etch-stop dielectric layer 121, the etch-stop dielectric cap rails 123 may optionally be collaterally recessed during the anisotropic etch process. The thickness of each portion of the etch-stop dielectric layer 121 that underlies a respective inter-line gap 125 may be in a range from 1% to 90%, such as from 10% to 70%, of the thickness of a portion of the etch-stop dielectric layer 121 that underlies a metal line portion 128N.

Referring to FIG. 15H, a dielectric material can be anisotropically deposited in peripheral portions of the inter-line gaps 125 and over the etch-stop dielectric cap rails 123 to form a dielectric material layer 126L, which is also referred to as a cavity-containing dielectric material layer, as described above with respect to the first embodiment. The air gaps 129 are formed inside or below the dielectric material layer 126L, as described above.

Referring to FIG. 15I, a chemical mechanical polishing (CMP) process can be performed to remove portions of the dielectric material layer 126L that are located above the horizontal plane including the top surfaces of the etch-stop dielectric cap rails 123. Each remaining portion of the dielectric material layer 126L located within the volume of a respective inter-line gap 125 constitutes a dielectric rail 126, as described above with respect to the first embodiment.

In one embodiment, at least one of the integrated line-and-via structures 128 may comprise a respective metallic barrier liner 128B comprising a conductive metal nitride material and a respective metal fill material portion 128M. In one embodiment, interfaces between at least one of the integrated line-and-via structures 128 and a respective pair of dielectric rails 126 may consist of interfaces between a metallic barrier liner 128B and the respective pair of dielectric rails 126. In one embodiment, at least one of the metallic barrier liners 128B may contact peripheral portions of a bottom surface of a respective one of the etch-stop dielectric cap rails 123. While the dielectric rails 126 of the second embodiment illustrated in FIG. 15I have the configuration of the dielectric rails 126 shown in the FIG. 14F, it should be noted that the dielectric rails of the second embodiment may alternatively have the configuration of the dielectric rails 126 shown in the FIG. 14G.

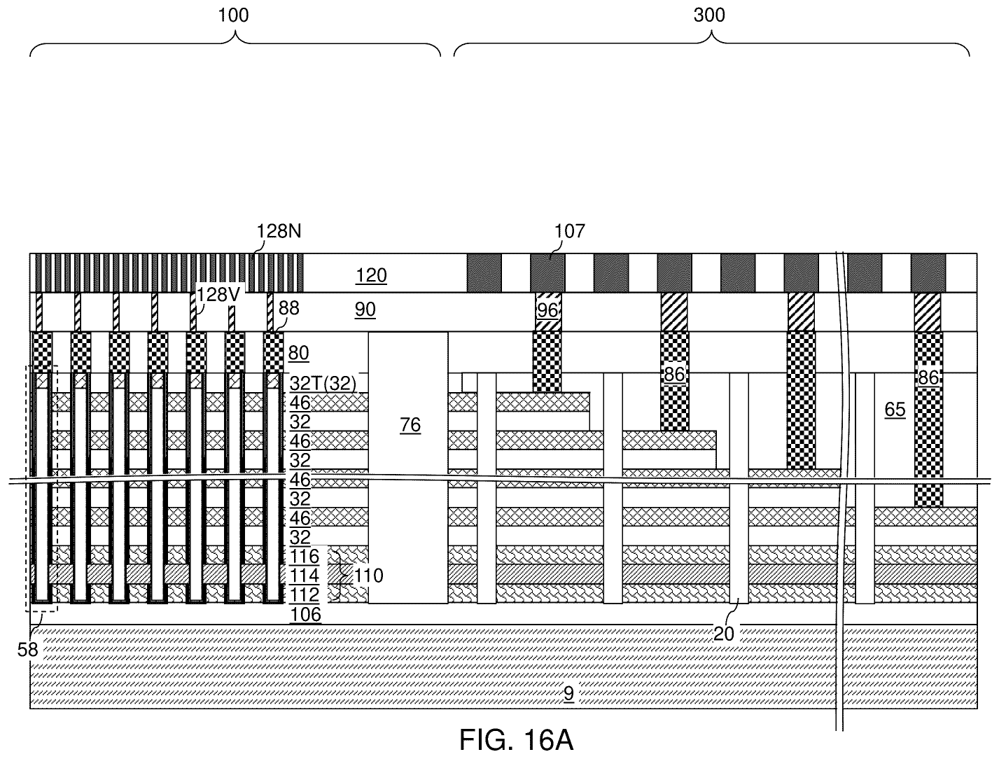

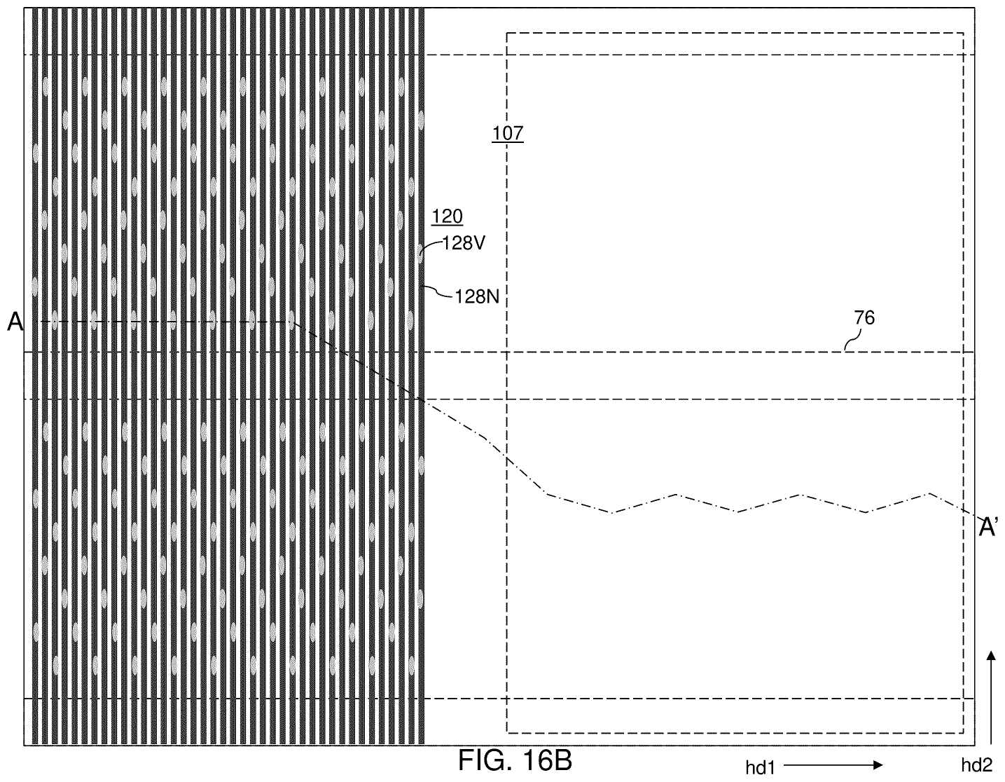

Referring to FIGS. 16A and 16B, the exemplary structure is illustrated after the processing steps described with reference to FIG. 14F or FIG. 14G or FIG. 15I. Generally, additional metal via structures can be formed in the first via-level dielectric layer 90 during formation of the via portions 128V of the integrated line-and-via structures 128, and additional metal line structures can be formed in the composite line-level dielectric layer 120 during formation of the metal line portions 128N of the integrated line-and-via structures 128. For example, the additional metal via structures may comprise layer-connection via structures 96 that contact a respective one of the layer contact via structures 86, and the additional metal line structures may comprise layer-connection metal lines 107. Each contiguous combination of a layer-connection metal line 107 and at least one layer-connection via structure 96 may be formed as an integrated line-and-via structure.

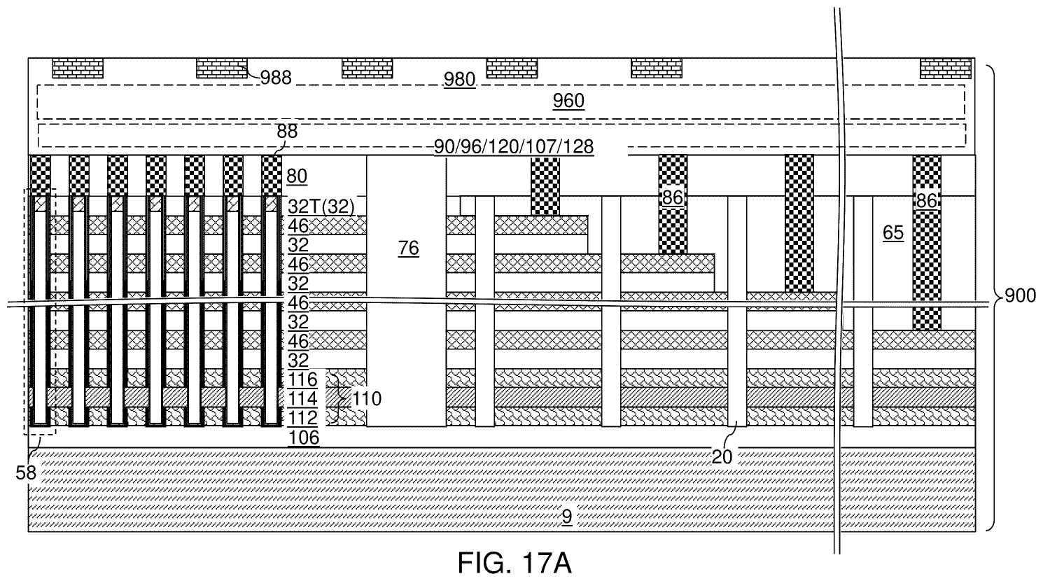

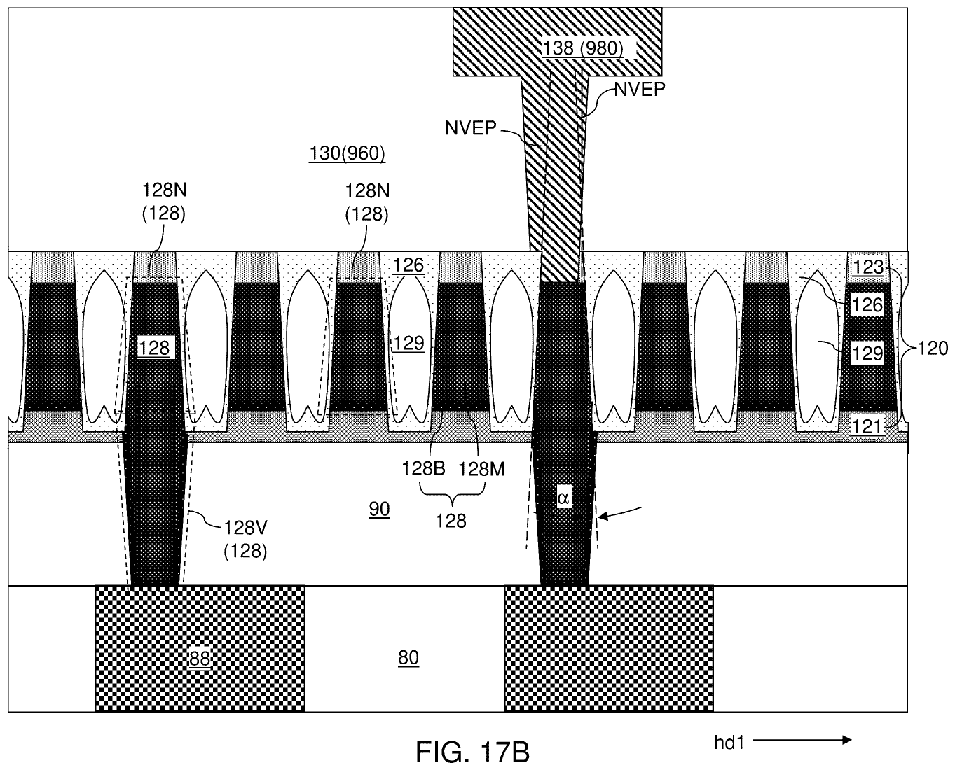

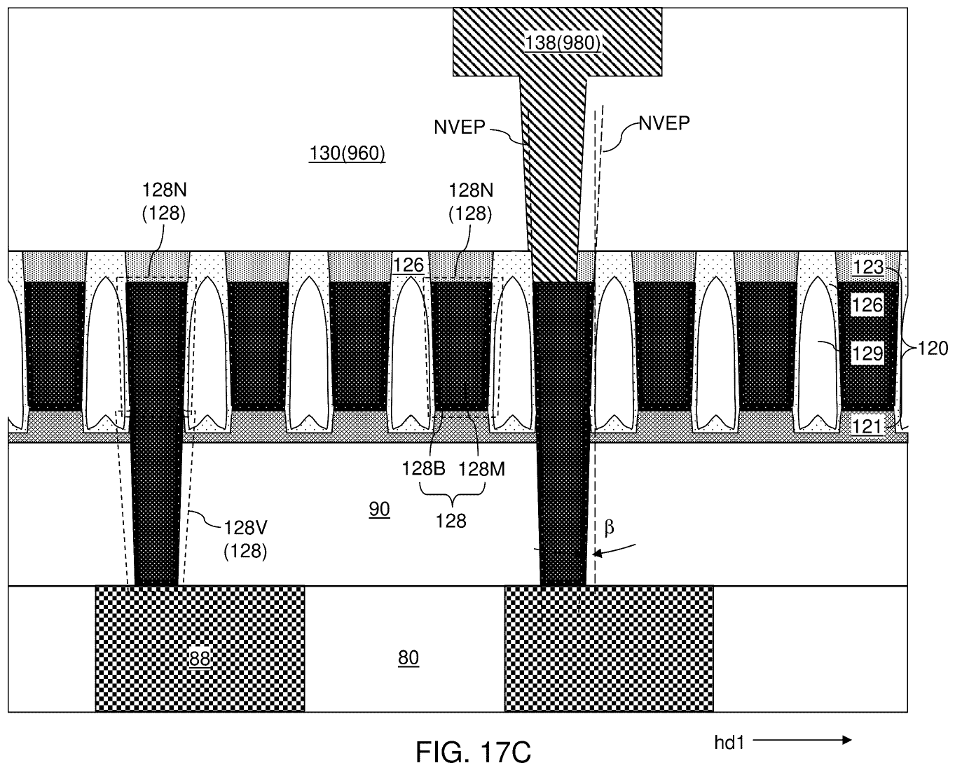

Referring to FIGS. 17A, 17B, and 17C, additional dielectric material layers and additional metal interconnect structures can be formed over the composite line-level dielectric layer 120. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960.

In an illustrative example, the memory-side dielectric material layers 960 may comprise a line-and-via-level dielectric material layer 130 embedding line-and-via-level interconnect structures 138 as illustrated in FIGS. 17B and 17C. FIG. 17B illustrates a structure of the first embodiment and FIG. 17C illustrates a structure of the second embodiment. The line-and-via-level interconnect structures 138 are a subset of the memory-side metal interconnect structures 980. At least one of the integrated line-and-via structures 128 may be contacted by a respective one of the line-and-via-level interconnect structures 138. In one embodiment, an anisotropic etch process that patterns via cavities through the line-and-via-level dielectric material layer 130 may have an etch chemistry that etches the materials of the line-and-via-level dielectric material layer 130 and the etch-stop dielectric cap rails 123 selective to the dielectric material of the dielectric rails 126. In this case, the via portion of at least one of the line-and-via-level interconnect structures 138 may have a stepped sidewall including a first sidewall segment that is contained within a non-vertical Euclidean plane NVEP within which a tapered metallic sidewall of a metal line portion 128N is located; a second sidewall segment that contacts a sidewall of the line-and-via-level dielectric material layer 130, and a horizontal surface segment that connects the first sidewall segment and the second sidewall segment and contacting a top surface segment of one of the dielectric rails 126. Thus, the via portions of the line-and-via-level interconnect structures 138 can be self-aligned to a respective underlying line-and-via structure 128 to provide enhanced electrical reliability for interconnection among the integrated line-and-via structures 128 and the line-and-via-level interconnect structures 138.

Referring to FIG. 17A, metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

In summary, a memory die 900 comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, the electrically conductive layers 46 comprise word lines of the two-dimensional array of NAND strings. The metal line portions 128N of the integrated line-and-via structures 128 may be employed as bit lines of the two-dimensional array of NAND strings.

Referring to FIG. 18, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

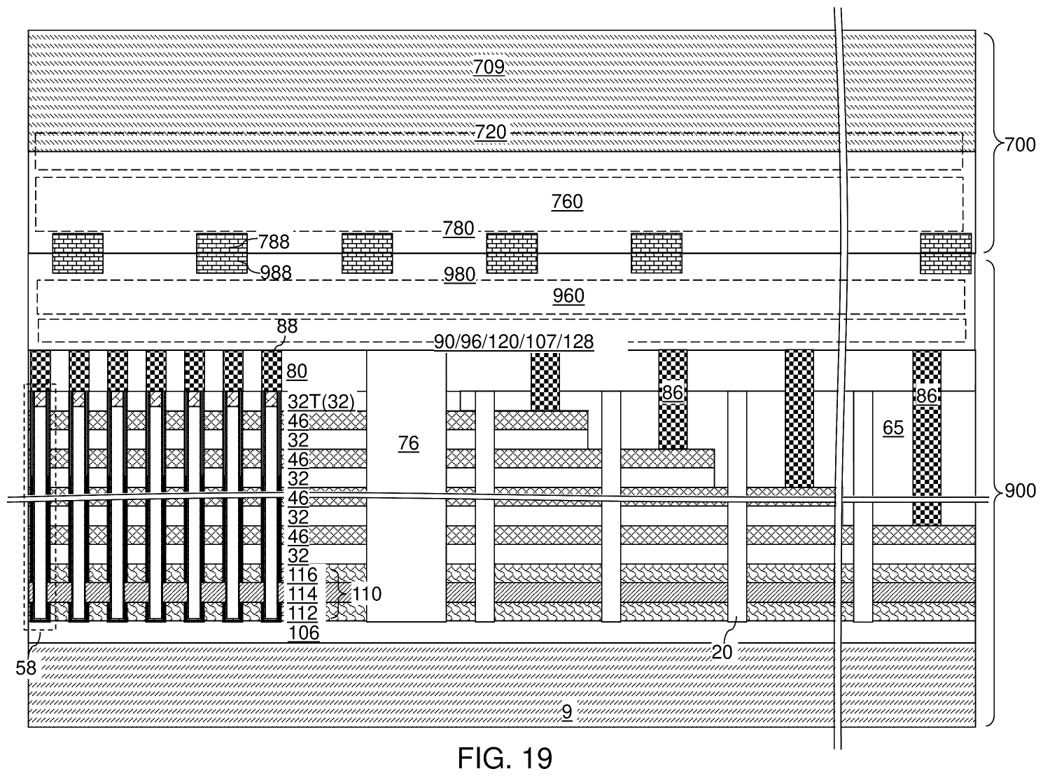

Referring to FIG. 19, a bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

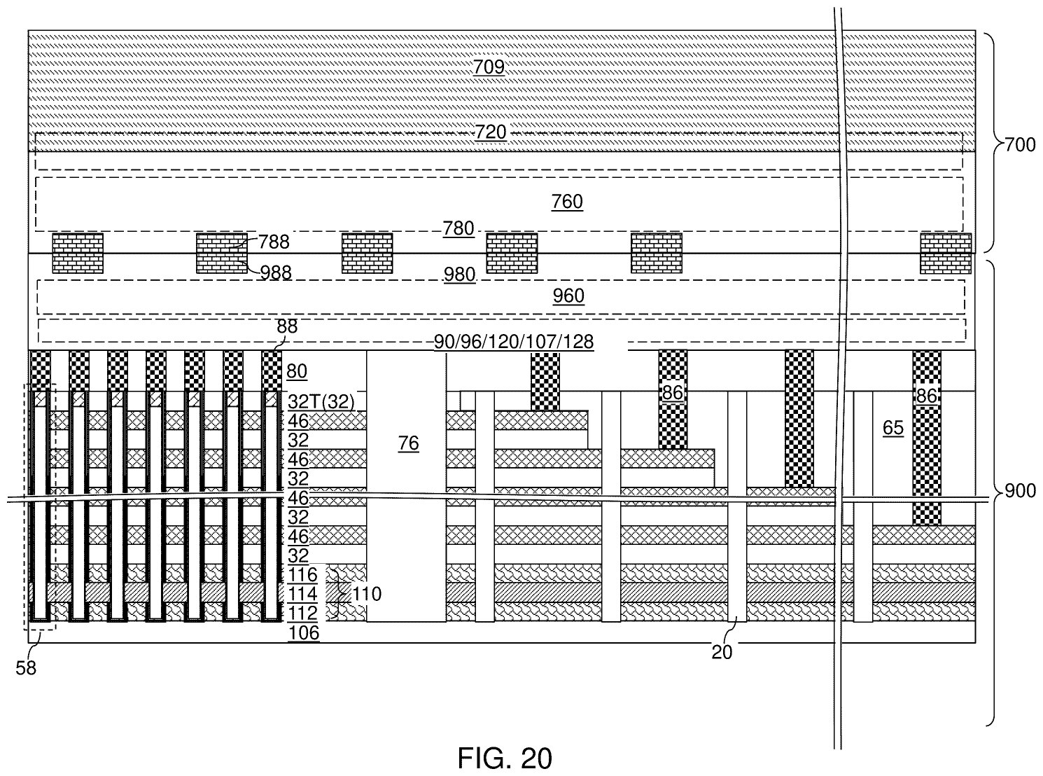

Referring to FIG. 20, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the stopper insulating layer 106 may be subsequently employed as a polishing stopper material layer. If an etch process such as a wet etch process is employed to remove the carrier substrate 9, the stopper insulating layer 106 may be subsequently employed as an etch stop material layer.

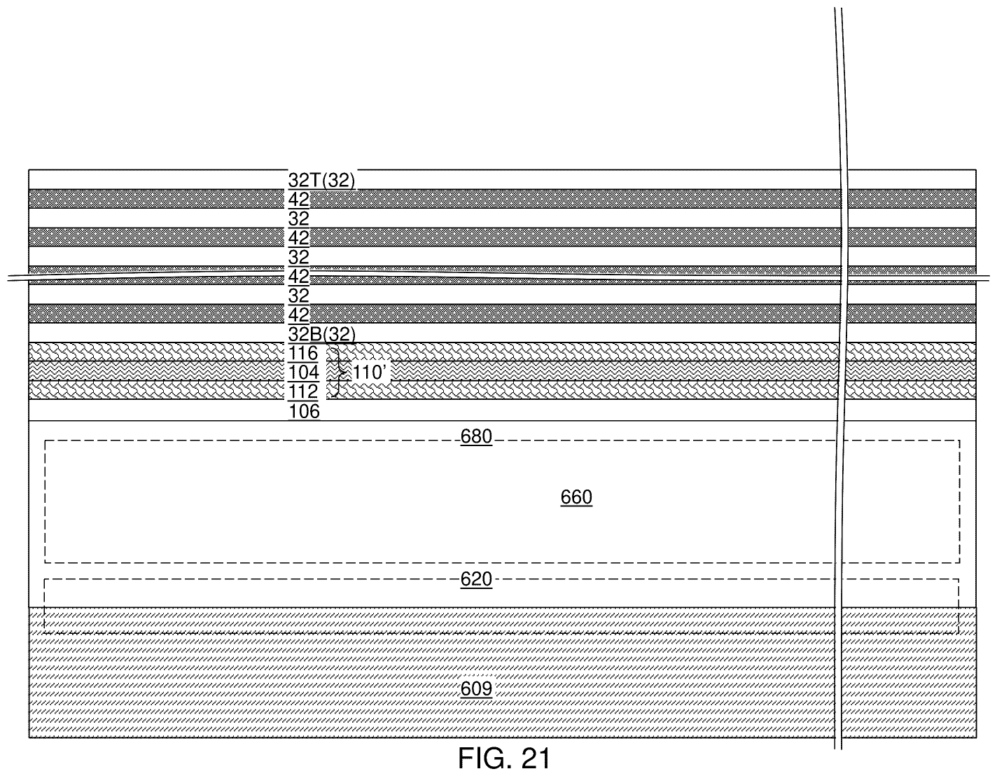

FIG. 21 illustrates an alternative configuration of the exemplary structure according to an alternative embodiment. The alternative configuration of the exemplary structure can be provided by forming semiconductor devices 620 comprising a peripheral circuit for controlling operation of a three-dimensional memory device on a semiconductor substrate 609, by forming metal interconnect structures 680 embedded in dielectric material layers 660 over the semiconductor devices 620, and then forming the structural elements described with reference to FIG. 7. In other words, the combination of the semiconductor substrate 609, the semiconductor devices 620, the dielectric material layers 660, and the metal interconnect structures 680 can be employed in lieu of the carrier substrate 9 and the stopper insulating layer 106.

Referring to FIG. 22, the processing steps described with reference to FIGS. 2-17C can be performed to provide a memory die, which may, or may not, be bonded to a logic die 700. In case the memory die of FIG. 20 is bonded to a logic die 700, the semiconductor devices 620 may comprise a first subset of a peripheral circuit for controlling operation of a three-dimensional memory device, and the logic die 700 may comprise a second subset of the peripheral circuit for controlling operation of a three-dimensional memory device.

Referring to all drawings and according to various embodiments of the present disclosure, a semiconductor structure is provided, which comprises: a contact-level dielectric layer 80 overlying semiconductor devices (such as the memory opening fill structures 58); contact-level metal structures (such as drain contact via structures 88) embedded in the contact-level dielectric layer 80 and electrically connected to a respective electrical node of the semiconductor devices; a via-level dielectric layer (such as a first via-level dielectric layer 90) overlying the contact-level dielectric layer 80; an etch-stop dielectric layer 121 overlying the via-level dielectric layer (such as a first via-level dielectric layer 90); integrated line-and-via structures 128 each comprising a metal line portion 128N and at least one via portion, wherein each via portion of the integrated line-and-via structures 128 vertically extends through the etch-stop dielectric layer 121 and the via-level dielectric layer (such as a first via-level dielectric layer 90) and contacts a top surface of a respective one of the contact-level metal structures (such as drain contact via structures 88), and the metal line portions 128N are laterally spaced apart among one another along a first horizontal direction hd1 and laterally extend along a second horizontal direction hd2; discrete (e.g., laterally separated along the first horizontal direction hd1) etch-stop dielectric cap rails 123 that overlie top surfaces of the metal line portions 128N; dielectric rails 126 located between neighboring pairs of metal line portions of the metal line portions 128N; and air gaps 129 located between neighboring pairs of the metal line portions 128N and at least partially enclosed by the respective dielectric rails 126.

In one embodiment, one of the metal line portions 128N comprises a pair of tapered metallic sidewalls that are contained within a pair of non-vertical Euclidean planes NVEP that laterally extend along the second horizontal direction hd2. In one embodiment, one of the etch-stop dielectric cap rails 123 contacts a top surface of said one of the metal line portions 128N, and comprises a pair of tapered dielectric sidewalls that are contained within the pair of non-vertical Euclidean planes NVEP.

In one embodiment, the etch-stop dielectric layer 121 comprises a silicon nitride or a silicon carbonitride layer; the discrete etch-stop dielectric cap rails 123 comprise silicon nitride or a silicon carbonitride rails; and the dielectric rails 126 comprise silicon carbide or silicon oxycarbide rails.

In the first embodiment, one of the metal line portions 128N comprises a top surface having a first width w1 along the first horizontal direction hd1 and comprises a bottom surface having a second width w2 along the first horizontal direction hd1; and the second width w2 is greater than the first width w1.

In the second embodiment, one of the metal line portions 128N comprises a top surface having a first width w1 along the first horizontal direction hd1 and comprises a bottom surface having a second width w2 along the first horizontal direction hd1; and the second width w2 is less than the first width w1.

In one embodiment shown in FIG. 14F, a first air gap 129 of the air gaps 129 is located entirely within a respective one of the dielectric rails 126; an entirety of surfaces of the first air gap 129 consists of inner dielectric surfaces of one of the dielectric rails 126; and the first air gap 129 is completely enclosed by the respective one of the dielectric rails 126. In this embodiment, the dielectric rails 126 have planar bottom surfaces that are contained between a horizontal plane including a top surface of the etch-stop dielectric layer 121 and a horizontal plane including a bottom surface of the etch-stop dielectric layer 121. In this embodiment, one of the dielectric rails 126 comprises: a bottom surface contacting a recessed horizontal surface of the etch-stop dielectric layer 121; a pair of lower tapered sidewalls contacting sidewalls of the etch-stop dielectric layer 121; and a pair of upper tapered sidewalls contacting sidewalls of a pair of metal line portions 128N of the integrated line-and-via structures 128.

In an alternative embodiment shown in FIG. 14G, a first air gap 129 of the air gaps 129 is located entirely below a respective one of the dielectric rails 126; an upper surface of the first air gap comprises a lower dielectric surface of the respective one of the dielectric rails 126; a lower surface of the first air gap comprises an upper dielectric surface of the etch-stop dielectric layer 121; and the first air gap 129 is partially enclosed by the respective one of the dielectric rails 126.

In the first embodiment, one of the integrated line-and-via structures 128 comprises a metallic barrier liner 128B comprising a conductive metal nitride material and a metal fill material portion 128M; interfaces between the one of the integrated line-and-via structures 128 and a pair of dielectric rails 126 of the dielectric rails 126 comprises interfaces between the metal fill material portion 128M and the pair of dielectric rails 126; and the metallic barrier liner 128B contacts lower portions of sidewalls of the pair of dielectric rails 126.

In the second embodiment, one of the integrated line-and-via structures 128 comprises a metallic barrier liner 128B comprising a conductive metal nitride material and a metal fill material portion 128M; interfaces between said one of the integrated line-and-via structures 128 and a pair of dielectric rails 126 of the dielectric rails 126 consist of interfaces between the metallic barrier liner 128B and the pair of dielectric rails 126; and the metallic barrier liner 128B contacts peripheral portions of a bottom surface of one of the etch-stop dielectric cap rails 123.

In one embodiment, the dielectric rails 126 have planar top surfaces that are contained within a horizontal plane including top surfaces of the etch-stop dielectric cap rails 123. In one embodiment, a vertical cross-sectional profile of one of the air gaps 129 along a vertical plane that is perpendicular to the second horizontal direction hd2 has a pointed tip portion having a decreasing width as a function of an increasing distance from a horizontal plane including a bottom surface of the etch-stop dielectric layer 121.

In one embodiment, the semiconductor devices comprise three-dimensional memory devices comprising an alternating stack of insulating layers 32 and electrically conductive layers 46, and memory opening fill structures 58 each comprising a memory film 50 and a vertical semiconductor channel 60 extending through the alternating stack, wherein the metal line portions 128N comprise bit lines of the three-dimensional memory devices.

The various embodiments of the present disclosure may be employed to provide nested metal lines (such as the metal line portions 128N) that are laterally spaced from each other by the air gaps 129. The air gaps provide a low dielectric constant environment (having a dielectric constant of about 1.00), which can be advantageously employed to reduce the RC delay in the electrical signals that are transmitted through the nested metal lines.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a contact-level dielectric layer overlying semiconductor devices;
contact-level metal structures embedded in the contact-level dielectric layer and electrically connected to a respective electrical node of the semiconductor devices;
a via-level dielectric layer overlying the contact-level dielectric layer;
an etch-stop dielectric layer overlying the via-level dielectric layer;
integrated line-and-via structures each comprising a metal line portion and at least one via portion, wherein each via portion of the integrated line-and-via structures vertically extends through the etch-stop dielectric layer and the via-level dielectric layer and contacts a top surface of a respective one of the contact-level metal structures, and the metal line portions are laterally spaced apart from each other along a first horizontal direction and laterally extend along a second horizontal direction;
discrete etch-stop dielectric cap rails that overlie top surfaces of the respective metal line portions;
dielectric rails located between neighboring pairs of metal line portions of the metal line portions; and
air gaps located between neighboring pairs of the metal line portions and at least partially enclosed by the respective dielectric rails.

2. The semiconductor structure of claim 1, wherein:
one of the metal line portions comprises a pair of tapered metallic sidewalls that are contained within a pair of non-vertical Euclidean planes that laterally extend along the second horizontal direction; and
one of the etch-stop dielectric cap rails contacts a top surface of said one of the metal line portions, and comprises a pair of tapered dielectric sidewalls that are contained within the pair of non-vertical Euclidean planes.

3. The semiconductor structure of claim 1, wherein:
the etch-stop dielectric layer comprises a silicon nitride or a silicon carbonitride layer;
the discrete etch-stop dielectric cap rails comprise silicon nitride or a silicon carbonitride rails; and
the dielectric rails comprise silicon carbide or silicon oxycarbide rails.

4. The semiconductor structure of claim 1, wherein:
one of the metal line portions comprises a top surface having a first width along the first horizontal direction and comprises a bottom surface having a second width along the first horizontal direction; and
the second width is greater than the first width.

5. The semiconductor structure of claim 1, wherein:
one of the metal line portions comprises a top surface having a first width along the first horizontal direction and comprises a bottom surface having a second width along the first horizontal direction; and
the second width is less than the first width.

6. The semiconductor structure of claim 1, wherein:
a first air gap of the air gaps is located entirely within a respective one of the dielectric rails;
an entirety of surfaces of the first air gap consists of inner dielectric surfaces of one of the dielectric rails; and
the first air gap is completely enclosed by the respective one of the dielectric rails.

7. The semiconductor structure of claim 6, wherein the dielectric rails have planar bottom surfaces that are contained between a horizontal plane including a top surface of the etch-stop dielectric layer and a horizontal plane including a bottom surface of the etch-stop dielectric layer.

8. The semiconductor structure of claim 7, wherein one of the dielectric rails comprises:
a bottom surface contacting a recessed horizontal surface of the etch-stop dielectric layer;
a pair of lower tapered sidewalls contacting sidewalls of the etch-stop dielectric layer; and
a pair of upper tapered sidewalls contacting sidewalls of a pair of metal line portions of the integrated line-and-via structures.

9. The semiconductor structure of claim 1, wherein:
a first air gap of the air gaps is located entirely below a respective one of the dielectric rails;
an upper surface of the first air gap comprises a lower dielectric surface of the respective one of the dielectric rails;
a lower surface of the first air gap comprises an upper dielectric surface of the etch-stop dielectric layer; and
the first air gap is partially enclosed by the respective one of the dielectric rails.

10. The semiconductor structure of claim 1, wherein:
the dielectric rails have planar top surfaces that are contained within a horizontal plane including top surfaces of the etch-stop dielectric cap rails; and
a vertical cross-sectional profile of one of the air gaps along a vertical plane that is perpendicular to the second horizontal direction has a pointed tip portion having a decreasing width as a function of an increasing distance from a horizontal plane including a bottom surface of the etch-stop dielectric layer.

11. The semiconductor structure of claim 1, wherein:
one of the integrated line-and-via structures comprises a metallic barrier liner comprising a conductive metal nitride material and a metal fill material portion;
interfaces between the one of the integrated line-and-via structures and a pair of dielectric rails of the dielectric rails comprises interfaces between the metal fill material portion and the pair of dielectric rails; and
the metallic barrier liner contacts lower portions of sidewalls of the pair of dielectric rails.

12. The semiconductor structure of claim 1, wherein:
one of the integrated line-and-via structures comprises a metallic barrier liner comprising a conductive metal nitride material and a metal fill material portion;
interfaces between the one of the integrated line-and-via structures and a pair of dielectric rails of the dielectric rails consist of interfaces between the metallic barrier liner and the pair of dielectric rails; and
the metallic barrier liner contacts peripheral portions of a bottom surface of one of the etch-stop dielectric cap rails.

13. The semiconductor structure of claim 1, wherein the semiconductor devices comprise three-dimensional memory devices comprising an alternating stack of insulating layers and electrically conductive layers, and memory opening fill structures each comprising a memory film and a vertical semiconductor channel extending through the alternating stack, wherein the metal line portions comprise bit lines of the three-dimensional memory devices.

14. A method of forming a device structure, comprising:
forming contact-level metal structures embedded in a contact-level dielectric layer;
forming a via-level dielectric layer over the contact-level dielectric layer;
forming an etch-stop dielectric layer over the via-level dielectric layer;
forming via cavities through the etch-stop dielectric layer and the via-level dielectric layer;
forming at least one metallic material layer in the via cavities and over the etch-stop dielectric layer;
forming an etch-stop dielectric cap material layer over the at least one metallic material layer;
patterning the etch-stop dielectric cap material layer and the at least one metallic material layer, wherein patterned portions of the at least one metallic material layer comprise integrated line-and-via structures each comprising a metal line portion and at least one via portion, wherein each via portion of the integrated line-and-via structures vertically extends through the etch-stop dielectric layer and the via-level dielectric layer and contacts a top surface of a respective one of the contact-level metal structures, and the metal line portions are laterally spaced apart from each other along a first horizontal direction and laterally extend along a second horizontal direction, and wherein patterned portions of the etch-stop dielectric cap material layer comprise etch-stop dielectric cap rails that overlie top surfaces of the metal line portions; and
forming dielectric rails between neighboring pairs of metal line portions of the metal line portions.

15. The method of claim 14, wherein:
the dielectric rails are formed by anisotropically depositing a dielectric material into gaps between the metal line portions of the integrated line-and-via structures, and by removing portions of the dielectric material from above a horizontal plane including top surfaces of the metal line portions; and
air gaps are located between neighboring pairs of the metal line portions and are at least partially enclosed by the respective dielectric rails.

16. The method of claim 14, wherein:
one of the metal line portions has a top surface having a first width along the first horizontal direction and a bottom surface having a second width along the first horizontal direction and contacting a top surface of the etch-stop dielectric layer; and
the second width is greater than the first width.

17. A method of forming a device structure, comprising:
forming contact-level metal structures embedded in a contact-level dielectric layer;
forming a via-level dielectric layer over the contact-level dielectric layer;
forming an etch-stop dielectric layer over the via-level dielectric layer;
forming a sacrificial template material layer over the etch-stop dielectric layer;
forming integrated line-and-via cavities, wherein each of the integrated line-and-via cavities comprises a respective line cavity that is formed through the sacrificial template material layer and at least one via cavity that is formed through the etch-stop dielectric layer and the via-level dielectric layer;
forming integrated line-and-via structures in the integrated line-and-via cavities, wherein each of the integrated line-and-via structures comprises a metal line portion and at least one via portion;
forming recess cavities by vertically recessing the metal line portions of the integrated line-and-via structures;
forming etch-stop dielectric cap rails in the recess cavities;
removing remaining portions of the sacrificial template material layer; and
forming dielectric rails between neighboring pairs of metal line portions of the metal line portions.

18. The method of claim 17 wherein:
the dielectric rails are formed by anisotropically depositing a dielectric material into gaps between the metal line portions of the integrated line-and-via structures, and by removing portions of the dielectric material from above a horizontal plane including top surfaces of the metal line portions; and
air gaps are located between neighboring pairs of the metal line portions and are at least partially enclosed by the respective dielectric rails.

19. The method of claim 17, wherein:
the metal line portions of the integrated line-and-via structures are laterally spaced apart from each other along a first horizontal direction and laterally extend along a second horizontal direction;
one of the metal line portions has a top surface having a first width along the first horizontal direction and a bottom surface having a second width along the first horizontal direction and contacting a top surface of the etch-stop dielectric layer; and
the second width is less than the first width.

20. The method of claim 17, further comprising vertically recessing portions of the etch-stop dielectric layer that are not covered by the integrated line-and-via structures after removal of the remaining portions of the sacrificial template material layer, wherein the dielectric rails are formed above recessed surfaces of the etch-stop dielectric layer.
